(19) United States
(12) Patent Application Publication
(10) Pub. No.: US 2026/0239848 A1
(43) Pub. Date: Aug. 13, 2026

(54) DISPLAY APPARATUS AND ELECTRONIC DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Hideaki SHISHIDO, Atsugi (JP)

(21) Appl. No.: 19/470,905

(22) PCT Filed: Apr. 15, 2024
(86) PCT No.: PCT/IB2024/053657

§ 371 Date: Sep. 30, 2025

(30) Foreign Application Priority Data
Apr. 21, 2023 (JP) 2023-069720

(51) Int. Cl. H10K 59/35; H10H 29/30; H10H 29/32; H10H 29/34; H10K 59/121; H10K 59/65

(52) U.S. Cl. CPC H10K 59/351; H10H 29/32; H10H 29/345; H10H 29/362; H10K 59/1213; H10K 59/352; H10K 59/65

(57) ABSTRACT

A display apparatus suitable for an under-display camera system is provided. The display apparatus includes a first display portion and a second display portion having the same pixel density. A first pixel included in the first display portion includes a subpixel R, a subpixel G, a subpixel B, and a subpixel W, and a second pixel included in the second display portion has a structure in which the subpixel W is removed from the first pixel and a light-transmitting region with an area equivalent to one subpixel is provided. By providing the second display portion and a lens of a camera to overlap with each other, imaging through the light-transmitting region can be performed.

### TECHNICAL FIELD

One embodiment of the present invention relates to a display apparatus.

Note that one embodiment of the present invention is not limited to the above technical field. Examples of the technical field of one embodiment of the present invention include a semiconductor apparatus, a display apparatus, a light-emitting apparatus, a power storage apparatus, a memory apparatus, an electronic device, a lighting apparatus, an input apparatus (e.g., a touch sensor), an input/output apparatus (e.g., a touch panel), driving methods thereof, and manufacturing methods thereof.

### BACKGROUND ART

In recent years, display apparatuses have found various applications and are widely used in smartphones, tablet terminals, and the like. Many portable terminals, such as smartphones, are provided with a front camera (on the display surface side) and a rear camera (on the opposite side of the display surface). The front camera is often used for capturing images of a user themselves.

Conventionally, the front camera has been typically provided outside a display portion; however, with the increasing demand for narrower bezels in portable terminals, it is increasingly being placed near or in the display portion. For example, a notch system in which a camera is provided to overlap with an area where part of a display portion is cut out, a punch-hole system in which a hole is made in a display portion and a camera is provided to overlap with the hole, and an under-display camera system in which a camera is placed overlapping with a display portion are known.

In the under-display camera system, imaging is performed by capturing light passed between pixels into the camera. For example, Patent Document 1 discloses a method in which a hole region where external light can pass through is provided between pixels and a low-quality image obtained through the hole region is processed so that a high-quality image is obtained.

### REFERENCE

### Patent Document

[Patent Document 1] Japanese Published Patent Application No. 2022-41886

### SUMMARY OF THE INVENTION

### Problems to be Solved by the Invention

The under-display camera system requires devising a way to capture as much light (information) as possible into the camera. For example, a method of making the area occupied by a pixel smaller in a region of a display portion overlapping with a camera than in other regions to increase the amount of light passed between pixels, is used.

Since the region overlapping with the camera is small in comparison to the entire display portion, reducing the area occupied by a pixel in the region does not have a significant influence on visual recognition. However, in some viewing angle at which the display portion is seen, the region is clearly recognized and display looks unnatural. When the area occupied by a pixel in the region is increased so that the region is not visually recognized, the amount of information that can be obtained by the camera is reduced and thus the image quality is degraded. Even in the case where image processing is performed, the poorer the quality of the obtained image is, the more difficult it is to obtain a high-quality image.

Thus, one object of one embodiment of the present invention is to provide a display apparatus suitable for an under-display camera system. Another object is to provide a display apparatus in which a region of a display portion that overlaps with a camera is less likely to be visually recognized. Another object is to provide a display apparatus with low power consumption. Another object is to provide a display apparatus with high luminance. Another object is to provide a highly reliable display apparatus. Another object is to provide an electronic device including the display apparatus.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention relates to a display apparatus suitable for an under-display camera system and an electronic device using the display apparatus.

One embodiment of the present invention is a display apparatus including a first display portion and a second display portion. The second display portion is surrounded by the first display portion, the first display portion includes a first pixel, the second display portion includes a second pixel, the first pixel includes first to fourth subpixels emitting light of different colors, and the second pixel includes fifth to seventh subpixels emitting light of different colors and a light-transmitting region.

The area occupied by a pixel and the pixel density can be the same between the first display portion and the second display portion.

The first and fifth subpixels can each have a function of emitting red light, the second and sixth subpixels can each have a function of emitting green light, the third and seventh subpixels can each have a function of emitting blue light, and the fourth subpixel can have a function of emitting white light.

Each of the first to seventh subpixels can include a light-emitting device emitting white light, and each of the first to third subpixels and the fifth to seventh subpixels can emit light to the outside through a coloring layer.

The first to fourth subpixels can be arranged in a matrix, and the fifth to seventh subpixels can be arranged in a manner similar to that of the first to third subpixels.

Another embodiment of the present invention is a display apparatus including a first display portion and a second display portion. The second display portion is surrounded by the first display portion, the first display portion includes a first pixel, the second display portion includes a second pixel, the first pixel includes first to fourth subpixels, the second pixel includes fifth to eighth subpixels and a light-transmitting region, the first and fifth subpixels each have a function of emitting red light, the second and sixth subpixels each have a function of emitting green light, the third and seventh subpixels each have a function of emitting blue light, the fourth and eighth subpixels each have a function of emitting white light, the area of the eighth subpixel is smaller than the area of the fourth subpixel, and the area occupied by a pixel and the pixel density are the same between the first display portion and the second display portion.

Each of the first to eighth subpixels can include a light-emitting device emitting white light, and each of the first to third subpixels and the fifth to seventh subpixels can emit light to the outside through a coloring layer.

Each of the first and second pixels preferably includes a transistor including a metal oxide in a semiconductor layer. As the transistor, a transistor with a channel formation region provided along a side surface of an insulating layer can also be used.

An electronic device which includes the display apparatus and a camera and includes a region where the second display portion overlaps with a lens is also one embodiment of the present invention.

### Effect of the Invention

According to one embodiment of the present invention, a display apparatus suitable for an under-display camera system can be provided. Alternatively, a display apparatus in which a region of a display portion that overlaps with a camera is less likely to be visually recognized can be provided. Alternatively, a display apparatus with low power consumption can be provided. Alternatively, a display apparatus with high luminance can be provided. Alternatively, a highly reliable display apparatus can be provided. Alternatively, an electronic device including the display apparatus can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a diagram illustrating a display apparatus. FIG. 1B is a diagram illustrating a display portion.

FIG. 2A to FIG. 2C are diagrams illustrating pixels in a region of a display portion that overlaps with a camera and the vicinity thereof. FIG. 2D and FIG. 2E are diagrams illustrating pixels.

FIG. 3A1 to FIG. 3D2 are diagrams illustrating pixels.

FIG. 4A to FIG. 4C are diagrams illustrating pixels.

FIG. 5 is a diagram illustrating a pixel.

FIG. 6A is a block diagram illustrating a display apparatus. FIG. 6B and FIG. 6C are diagrams illustrating pixel circuits.

FIG. 7A and FIG. 7B are diagrams illustrating a vertical transistor.

FIG. 8A is a cross-sectional view illustrating an example of a display apparatus. FIG. 8B and FIG. 8C are cross-sectional views illustrating examples of transistors.

FIG. 9 is a cross-sectional view illustrating an example of a display apparatus.

FIG. 10 is a cross-sectional view illustrating an example of a display apparatus.

FIG. 11A and FIG. 11B are diagrams each illustrating an example of an electronic device.

FIG. 11C is a diagram illustrating a camera module.

### MODE FOR CARRYING OUT THE INVENTION

Embodiments will be described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the invention described below, the same reference numerals are used in common, in different drawings, for the same portions or portions having similar functions, and a repeated description thereof is omitted in some cases. Note that the hatching of the same component that constitutes a drawing is sometimes omitted or changed as appropriate in different drawings.

In addition, even in the case where a single component is illustrated in a circuit diagram, the component may be composed of a plurality of parts as long as there is no functional inconvenience. For example, in some cases, a plurality of transistors that operate as a switch are connected in series or in parallel. Furthermore, in some cases, capacitors are divided and arranged in a plurality of positions.

In addition, one conductor has a plurality of functions such as a wiring, an electrode, and a terminal in some cases. In this specification, a plurality of names are used for the same component in some cases. Furthermore, even in the case where elements are illustrated in a circuit diagram as if they were directly connected to each other, the elements may actually be connected to each other through one or more conductors. In this specification, even such a structure is included in the category of direct connection.

### Embodiment 1

In this embodiment, the display apparatus of one embodiment of the present invention will be described with reference to drawings.

One embodiment of the present invention is a display apparatus that can be used for an under-display camera type electronic device. The display apparatus includes a first display portion and a second display portion, and the second display portion is provided to be surrounded by the first display portion.

A first pixel included in the first display portion includes four subpixels and performs full-color display using red, green, blue, and white light. A second pixel included in the second display portion includes three subpixels and performs full-color display using red, green, and blue light. Since the first display portion includes the subpixel emitting white light, luminance can be easily increased and power consumption can be reduced.

The second pixel has a structure in which the subpixel emitting white light is removed from the first pixel, and a region that transmits light (hereinafter, a light-transmitting region) with an area equivalent to one subpixel is provided. The second display portion and a lens of a camera are provided to overlap with each other, enabling imaging through the light-transmitting region.

The area occupied by the pixel and the pixel density are the same between the first display portion and the second display portion. Accordingly, in the display apparatus of one embodiment of the present invention, the entire display portion can have uniform resolution and the position of the second display portion is less likely to be visually recognized; thus, the display apparatus is suitable as a display apparatus used for the under-display camera system.

Note that in this specification, the area occupied by a pixel refers to the area of a region required for arranging components (e.g., a subpixel, a light-transmitting region, and a wiring) of one pixel appropriately. Note that pixel density refers to the number of pixels per unit area or unit length.

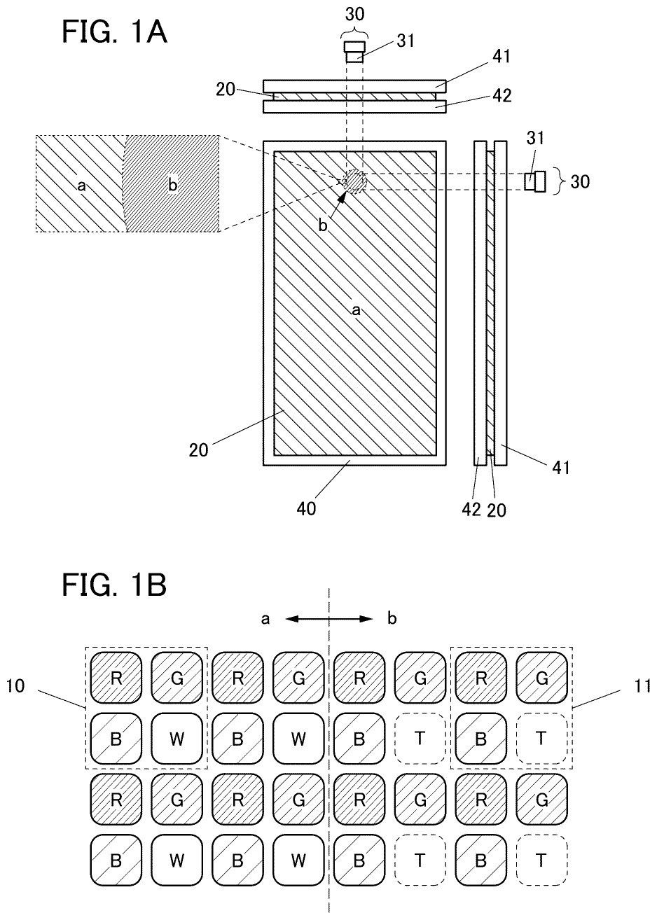

FIG. 1A is a schematic view illustrating the positional relation between the display apparatus of one embodiment of the present invention and a camera corresponding to a front camera, and illustrates a right side view on the right side and a plan view (an upper side view) on an upper side of a front view.

The display apparatus includes a display portion 20 between a substrate 41 and a substrate 42. Note that the substrate 42 is not illustrated in the front view. The display portion 20 includes a display portion a and a display portion b, and the display portion b is placed to be surrounded by the display portion a. The display portion b has a structure that easily transmits light, and includes a region overlapping with a camera 30 with the substrate 41 therebetween.

The camera 30 is a camera module for the front camera and has a structure in which a lens 31 is provided over an image sensor. The display portion b preferably has a size large enough to overlap with the entire lens 31 when seen from the display portion 20 side so that the camera 30 can capture a lot of light. Since the lens 31 has a circular shape, the shape of the display portion b is also preferably circular or substantially circular.

An enlarged view of the vicinity of the boundary between the display portion a and the display portion b is illustrated on the left side of the front view, and FIG. 1B is a further enlarged view illustrating an example of a pixel structure.

The display portion a includes a pixel 10. The pixel 10 includes four subpixels: a subpixel emitting red light (R), a subpixel emitting green light (G), a subpixel emitting blue light (B), and a subpixel emitting white light (W). In FIG. 1B, a corresponding color (R, G, B, and W) is shown in each subpixel. In the pixel 10, colors of the light emitted by the subpixels can be replaced as appropriate.

In the following description, the subpixel emitting red light (R) is referred to as a subpixel R, the subpixel emitting green light (G) is referred to as a subpixel G, the subpixel emitting blue light (B) is referred to as a subpixel B, and the subpixel emitting white light (W) is referred to as a subpixel W in some cases.

Basically, full-color display can be performed by providing the subpixel R, the subpixel G, and the subpixel B corresponding to the three primary colors of light (R, G, and B) in the pixel; power consumption can be reduced by adding the subpixel W. Furthermore, the luminance can be increased.

For example, in the case of performing white display, driving one subpixel W can reduce power consumption in comparison to the case of driving three subpixels of the subpixel R, the subpixel G, and the subpixel B to obtain white light emission. In particular, in the case where a light source emit white light and color filters are used for the subpixel R, the subpixel G, and the subpixel B, the amount of light is significantly attenuated. Thus, driving the subpixel W using no color filter has a large effect.

Since white light can be regarded as containing components of red light, green light, and blue light, colors created using red light, green light, and blue light can be created using white light and any one or two of red light, green light, and blue light. Accordingly, the number of subpixels to be driven can be reduced in some colors to be created and thus power consumption can be reduced.

Since white light substitutes for the combination of red light, green light, and blue light, making the subpixel W emit light is equivalent to with making all of the subpixel R, the subpixel G, and the subpixel B emit light. Thus, making four subpixels of the subpixel R, the subpixel G, the subpixel B, and the subpixel W emit light can increase the display luminance.

Since the display portion a having a large area is composed of the pixels 10 each including four subpixels of the subpixel R, the subpixel G, the subpixel B, and the subpixel W, power consumption can be reduced and luminance can be improved in the display portion 20.

The display portion b includes a pixel 11. The pixel 11 includes three subpixels: the subpixel R, the subpixel G, and the subpixel B. Note that in the pixel 11, colors of the light emitted by the subpixels can be replaced as appropriate.

The pixel 11 has a structure in which the subpixel W is removed from the pixel 10 and a light-transmitting region T with an area equivalent to one subpixel is provided. That is, the pixel 11 has a structure in which the subpixel W of the pixel 10 is replaced with the light-transmitting region T. The pixel 10 and the pixel 11 have the same external size and are provided at the same pitch (a gap between pixels). Thus, the area occupied by a pixel and the pixel density are the same between the display portion a and the display portion b.

Therefore, in the display portion 20, the entire area can have uniform resolution, and an image can be obtained using the camera 30 by utilizing the light-transmitting region T provided in the display portion b.

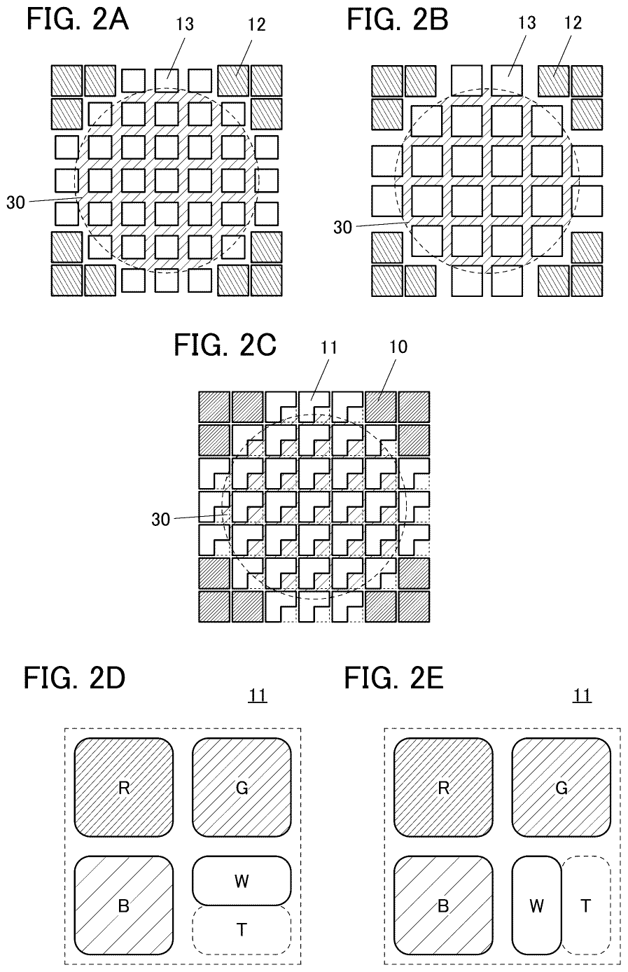

FIG. 2A and FIG. 2B are diagrams illustrating pixels in a region overlapping with the camera 30 and the vicinity thereof in a conventional display apparatus used for an under-display camera type electronic device. A pixel 12 is placed in a region not overlapping with the camera 30, and a pixel 13 is placed in the region overlapping with the camera 30.

In an example illustrated in FIG. 2A, the area occupied by the pixel 13 is made smaller than the area occupied by the pixel 12 in order to increase the amount of transmitted light to the camera 30. In that case, although the entire display portion has uniform pixel density, the pixel 13 needs to have higher emission intensity to match the luminance with the surroundings (the pixels 12) because the pixel 13 occupies a smaller area than the pixel 12. In that case, a light-emitting device of the pixel 13 needs to be applied with a voltage higher than that applied to a light-emitting device of the pixel 12; thus, the reliability of the light-emitting device of the pixel 13 decreases in some cases.

In an example illustrated in FIG. 2B, a pitch between the pixels 13 is made larger than a pitch between the pixels 12 in order to increase the amount of transmitted light to the camera 30. In that case, the area occupied by a pixel is the same between the pixel 12 and the pixel 13, but the resolution (pixel density) of the region overlapping with the camera 30 is lower than that of the peripheral portion. Consequently, the region is visually recognized, leading to unnatural display in some cases.

FIG. 2C is a diagram illustrating pixels in the region overlapping with the camera 30 and the vicinity thereof in the display apparatus to which one embodiment of the present invention illustrated in FIG. 1A and FIG. 1B is applied.

In one embodiment of the present invention, by providing four subpixels to the pixel 10 and three subpixels to the pixel 11, the area occupied by a pixel and the pixel density can be the same between the display portion a and the display portion b while ensuring the region for transmitting light to the camera 30. Therefore, effects on the reliability and the display quality of the light-emitting device described with reference to FIG. 2A and FIG. 2B can be suppressed.

Although the structure in which the pixel 11 does not include the subpixel W is described above as the example, the subpixel W with a rectangular shape can be provided as illustrated in FIG. 2D. In that case, in the pixel 11, the area of the subpixel W is made smaller than that of the subpixel W provided in the pixel 10 to ensure a region for providing the light-transmitting region T. With such a structure, an advantage of the subpixel W can also be given to the pixel 11.

Although FIG. 2D illustrates an example where the subpixel W and the light-transmitting region T have the same area ratio, the area ratio can be changed as appropriate in consideration of the quality of an image obtained by the camera 30, for example. In addition, although FIG. 2D illustrates an example in which one long side of the subpixel W is placed on the subpixel G side, one long side of the subpixel W can be placed on the subpixel B side as illustrated in FIG. 2E.

Although FIG. 1B, FIG. 2D, and FIG. 2E illustrate examples where the subpixels are arranged in a matrix, there is no particular limitation on the arrangement of the subpixels, and a variety of arrangements can be employed. Examples of the arrangement of the subpixels that can be used include stripe arrangement, S-stripe arrangement, matrix arrangement, delta arrangement, Bayer arrangement, PenTile arrangement, and the like.

Examples of the top surface shape of the subpixel include polygons such as a triangle, a tetragon (including a rectangle and a square), and a pentagon; polygons with rounded corners; an ellipse; and a circle.

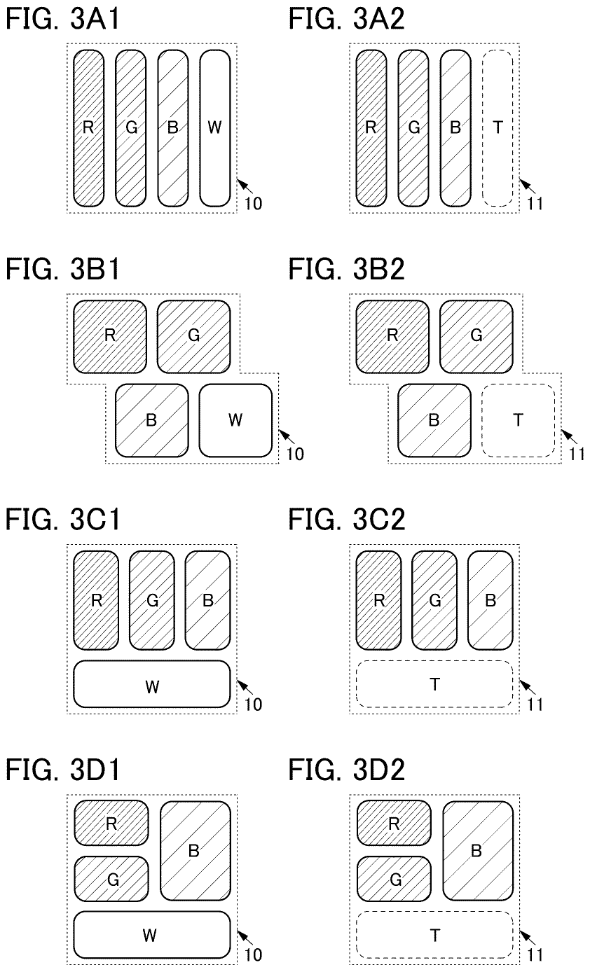

FIG. 3A1 and FIG. 3A2 are diagrams each illustrating examples in which the subpixels are arranged in a stripe pattern; FIG. 3A1 illustrates an application example of the pixel 10, and FIG. 3A2 illustrates an application example of the pixel 11.

FIG. 3B1 and FIG. 3B2 are diagrams each illustrating an example of (the) arrangement in which the subpixel W or the light-transmitting region T is added to the subpixel R, the subpixel G, and the subpixel B arranged in a delta, FIG. 3B1 is the example of the application to the pixel 10, and FIG. 3B2 is the example of the application to the pixel 11.

FIG. 3C1 and FIG. 3C2 are diagrams each illustrating an example in which one pixel is composed of two rows and three columns, FIG. 3C1 is the example of the application to the pixel 10, and FIG. 3C2 is the example of the application to the pixel 11. The pixels illustrated in FIG. 3C1 and FIG. 3C2 each include three subpixels (R, G, and B) in the upper row (first row) and one subpixel W or one light-transmitting region T in the lower row (second row). Since stripe arrangement is employed as the layout of R, G, and B in the pixels illustrated in FIG. 3C1 and FIG. 3C2, display quality can be improved.

FIG. 3D1 and FIG. 3D2 are diagrams each illustrating an example in which one pixel is composed of three rows and two columns, FIG. 3D1 is the example of the application to the pixel 10, and FIG. 3D2 is the example of the application to the pixel 11. The pixels illustrated in FIG. 3D1 and FIG. 3D2 include the subpixel R in the upper row (first row), the subpixel G in the middle row (second row), the subpixel B across the first and second rows, and one subpixel W or one light-transmitting region T in the lower row (third row). Since what is called S-stripe arrangement is employed as the layout of R, G, and B in the pixels illustrated in FIG. 3D1 and FIG. 3D2, display quality can be improved.

Note that in FIG. 3A1 to FIG. 3D2, colors of the light emitted from the subpixels can be replaced as appropriate.

At least part of this embodiment can be implemented in combination with any of the other embodiments described in this specification as appropriate.

### Embodiment 2

In this embodiment, a structure of a display apparatus of one embodiment of the present invention will be described. Note that each of a pixel and a subpixel including a light-emitting device, which are described in this embodiment respectively corresponds to the pixel 10, the pixel 11, or the subpixels (R, G, B, and W) described in Embodiment 1.

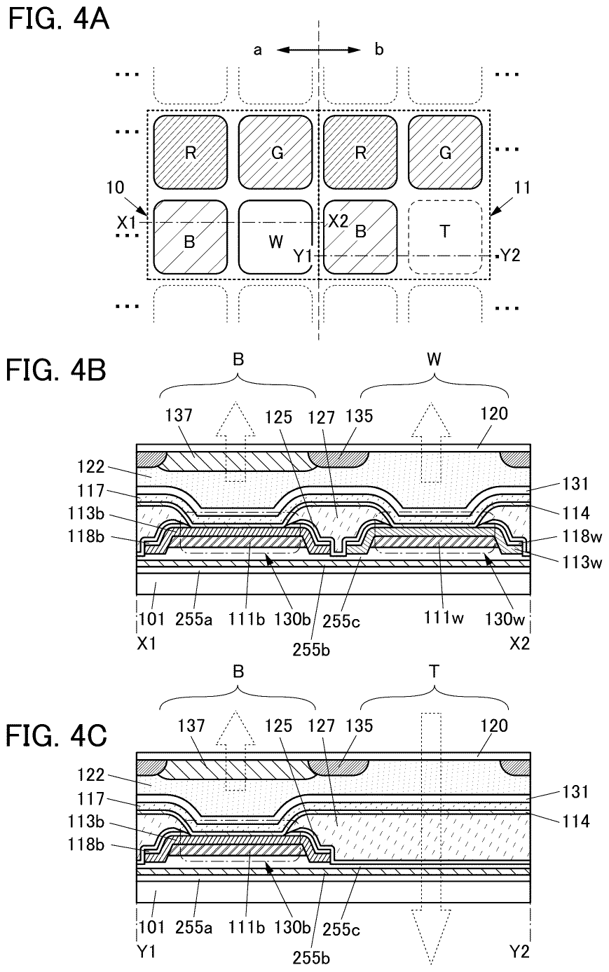

FIG. 4A illustrates part of FIG. 1B, and is an enlarged view of the display portion 20 of the display apparatus. The pixel 10 included in the display portion a is illustrated on the left side and the pixel 11 included in the display portion b is illustrated on the right side.

The display apparatus of one embodiment of the present invention includes the light-emitting device in the pixel. The pixel 10 includes the subpixel R, the subpixel G, the subpixel B, and the subpixel W. The pixel 11 includes the subpixel R, the subpixel G, and the subpixel B.

In the following description, the subpixel B and the subpixel W included in the pixel 10 and the subpixel B and the light-transmitting region T included in the pixel 11 will be described with reference to cross-sectional views. Note that components of the subpixel R and the subpixel G included in the pixel 10 and the pixel 11 are the same as those of the subpixel B except for the color of a coloring layer (color filter); thus, the description thereof will be omitted. A coloring layer transmitting red light is provided in the subpixel R. A coloring layer transmitting green light is provided in the subpixel G. A coloring layer transmitting blue light is provided in the subpixel B.

FIG. 4B is a cross-sectional view along X1-X2 of the pixel 10 illustrated in FIG. 4A. As illustrated in FIG. 4B, an insulating layer is provided over a layer 101, and light-emitting devices 130b and 130w are provided over the insulating layer. A protective layer 131 is provided to cover the light-emitting devices 130b and 130w. Note that the layer 101 can include a transistor included in a pixel circuit or the like.

A light-blocking layer 135 is bonded to the protective layer 131 with an adhesive layer 122 therebetween. The light-blocking layer 135 is provided between two subpixels adjacent to each other. With the use of the light-blocking layer 135, light leakage (stray light) to an adjacent subpixel can be inhibited. Thus, the display quality of the display apparatus can be improved.

In a conventional display apparatus used for an under-display camera system, a light-blocking layer is not provided to increase the light transmittance in a region overlapping with a camera; however, the stray light has been likely to occur and the display quality has been lowered. In one embodiment of the present invention, the area of the light-transmitting region T can be sufficiently ensured even when the light-blocking layer 135 is provided; thus, a high-quality image can be obtained. Note that also in one embodiment of the present invention, a structure in which the width of the light-blocking layer is made smaller in a region overlapping with a camera than in the other region or a structure in which the light-blocking layer is not used can be employed, so that the light transmittance can be improved.

FIG. 4B illustrates an example in which light from the light-emitting devices 130b and 130w is emitted toward a substrate 120 side.

In a region between the light-emitting device 130b and the light-emitting device 130w adjacent to each other, an insulating layer 125 and an insulating layer 127 over the insulating layer 125 are provided.

The light-emitting device will be described. The display apparatus of one embodiment of the present invention has a top-emission structure in which light is emitted in a direction opposite to the substrate where the light-emitting device is formed.

The layer 101 including transistors can employ a stacked-layer structure where a plurality of transistors are provided over a substrate and an insulating layer is provided to cover these transistors. The insulating layer over the transistors is not limited to a single-layer structure, and can have a stacked-layer structure. In FIG. 4B, a stack of an insulating layer 255a, an insulating layer 255b, and an insulating layer 255c is illustrated as the insulating layer over the transistors. When the insulating layer over the transistors has a stacked-layer structure, the reliability of the transistors can be improved.

As each of the insulating layer 255a, the insulating layer 255b, and the insulating layer 255c, a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as the insulating layer 255a and the insulating layer 255c and a silicon nitride film be used as the insulating layer 255b. The insulating layer 255b preferably has a function of an etching protective film.

Note that in this specification and the like, an oxynitride refers to a material that contains more oxygen than nitrogen in its composition, and a nitride oxide refers to a material that contains more nitrogen than oxygen in its composition. For example, in the case where silicon oxynitride is described, it refers to a material that contains more oxygen than nitrogen in its composition, and in the case where silicon nitride oxide is described, it refers to a material that contains more nitrogen than oxygen in its composition.

The color of the light emitted from the light-emitting devices 130b and 130w can be white. Furthermore, color purity can be increased when the light-emitting device has a microcavity structure.

As the light-emitting device, an OLED (Organic Light Emitting Diode) or a QLED (Quantum-dot Light Emitting Diode) is preferably used. Examples of a light-emitting substance contained in the light-emitting device include a substance that emits fluorescent light (a fluorescent material), a substance that emits phosphorescent light (a phosphorescent material), and a substance that exhibits thermally activated delayed fluorescence (a thermally activated delayed fluorescent (TADF) material). As the light-emitting substance included in the EL element, not only an organic compound but also an inorganic compound (a quantum dot material or the like) can be used. In addition, an LED (Light Emitting Diode) such as a micro LED can also be used as the light-emitting device.

One of a pair of electrodes of the light-emitting device functions as a cathode and the other electrode functions as an anode. The case where the pixel electrode functions as an anode and the common electrode functions as a cathode is described below as an example in some cases.

The light-emitting device 130b includes a pixel electrode 111b over the insulating layer 255c, an island-shaped layer 113b over the pixel electrode 111b, a common layer 114 over the layer 113b, and a common electrode 117 over the common layer 114. In the light-emitting device 130b, the layer 113b and the common layer 114 can be collectively referred to as an EL layer.

The light-emitting device 130w includes a pixel electrode 111w over the insulating layer 255c, an island-shaped layer 113w over the pixel electrode 111w, the common layer 114 over the layer 113w, and the common electrode 117 over the common layer 114. In the light-emitting device 130w, the layer 113w and the common layer 114 can be collectively referred to as an EL layer.

When the EL layer is provided in an island shape for each light-emitting device, a leakage current between adjacent light-emitting devices can be inhibited. Thus, it is possible to prevent light emission due to unintended crosstalk, so that a display apparatus with extremely high contrast can be achieved. Specifically, a display apparatus having high current efficiency at low luminance can be obtained.

The light-emitting device of this embodiment can have a tandem structure. A light-emitting device having a tandem structure includes two or more light-emitting units in the layer 113b and the layer 113w, and each light-emitting unit can include one or more light-emitting layers. Each of the light-emitting unit may include one or more of a hole-injection layer, a hole-transport layer, a hole-blocking layer, an electron-blocking layer, an electron-transport layer, and an electron-injection layer. A charge-generation layer is preferably provided between the light-emitting units. The charge-generation layer includes at least a charge-generation region.

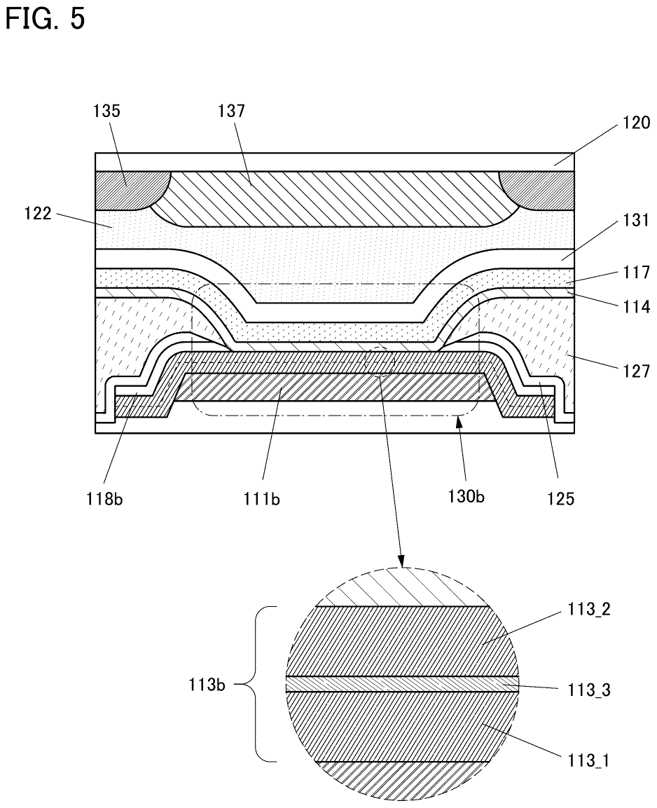

For example, the layer 113b and the layer 113w can have a stacked-layer structure of a light-emitting unit 113_1, a charge-generation layer 113_3, and a light-emitting unit 113_2 (see an enlarged view of the layer 113b in FIG. 5). Note that in the drawing used in this embodiment, the charge-generation layer is indicated by a dashed line in some cases.

To emit white light, a tandem structure in which light-emitting units emitting light of different colors are combined is preferably employed. To obtain white light emission, the structure is employed such that light emitted from a plurality of light-emitting units can be combined to be white light. For example, in the structure illustrated in FIG. 5, one of the light-emitting unit 113_1 and the light-emitting unit 113_2 emits blue light and the other emits yellow light. Alternatively, a light-emitting unit emitting red light and a light-emitting unit emitting cyan light may be combined. Alternatively, a light-emitting unit emitting green light and a light-emitting unit emitting magenta light may be combined.

Alternatively, three light-emitting units may be combined. For example, three light-emitting units: a light-emitting unit emitting red light, a light-emitting unit emitting green light, and a light-emitting unit emitting blue light, may be combined. Alternatively, three light-emitting units: a light-emitting unit emitting blue light, a light-emitting unit emitting yellow or yellowish-green light, and a light-emitting unit emitting blue light, may be combined. Alternatively, the following three light-emitting units can be combined: a light-emitting unit emitting blue light, a light-emitting unit emitting yellow, yellowish-green, or green and red light, and a light-emitting unit emitting blue light.

Examples of the number of stacked light-emitting units and the order of colors from an anode side include a two-layer structure of B (a light-emitting unit emitting blue light) and Y (a light-emitting unit emitting yellow light); a two-layer structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R (a light-emitting unit emitting red light) and Y; a two-layer structure of R and G; a two-layer structure of G and R; a three-layer structure of G, R, and G; and a three-layer structure of R, G, and R. Another layer may be provided between two light-emitting layers.

A light-emitting device having a tandem structure emitting light from a plurality of light-emitting units requires a relatively high voltage for light emission but requires a small amount of current for obtaining the emission intensity at the same level as that from a light-emitting device having a single structure (including one light-emitting unit). Thus, with the tandem structure, current stress on each light-emitting unit can be reduced and the element lifetime can be extended. That is, with a light-emitting device having a tandem structure, a highly reliable display apparatus can be formed.

It is preferable that the light-emitting unit 113_2 include a light-emitting layer and a carrier-transport layer (an electron-transport layer or a hole-transport layer) over the light-emitting layer in the structure illustrated in FIG. 5. Alternatively, the light-emitting unit 113_2 preferably includes a light-emitting layer and a carrier-blocking layer (a hole-blocking layer or an electron-blocking layer) over the light-emitting layer. Alternatively, the light-emitting unit 113_2 preferably includes a light-emitting layer, a carrier-blocking layer over the light-emitting layer, and a carrier-transport layer over the carrier-blocking layer. Since the surface of the light-emitting unit 113_2 is exposed in the fabrication process of the display apparatus, providing one or both of the carrier-transport layer and the carrier-blocking layer over the light-emitting layer inhibits the light-emitting layer from being exposed on the outermost surface, so that damage to the light-emitting layer can be reduced. Accordingly, the reliability of the light-emitting devices can be improved. Note that in the case where three or more light-emitting units are provided, the uppermost light-emitting unit preferably includes a light-emitting layer and one or both of a carrier-transport layer and a carrier-blocking layer over the light-emitting layer.

The common layer 114 can include an electron-injection layer or a hole-injection layer. Alternatively, the common layer 114 can include a stack of an electron-transport layer and an electron-injection layer. Alternatively, the common layer 114 can include a stack of a hole-transport layer and a hole-injection layer. The common layer 114 and the common electrode 117 are shared by the light-emitting devices included in the subpixels.

In FIG. 4B, the layer 113b is formed to cover the end portion of the pixel electrode 111b. A mask layer 118b is positioned over the layer 113b of the light-emitting device 130b. The mask layer 118b is a remaining part of a mask layer provided in contact with the top surface of the layer 113b at the time of processing the layer 113b.

In FIG. 4B, the layer 113w is formed to cover the end portion of the pixel electrode 111w. A mask layer 118w is positioned over the layer 113w included in the light-emitting device 130w. The mask layer 118w is a remaining part of a mask layer provided in contact with the top surface of the layer 113w at the time of processing the layer 113w.

The side surfaces of the layer 113b and the layer 113w are covered with the insulating layer 125. The insulating layer 127 overlaps with the side surfaces of the layer 113b and the layer 113w with the insulating layer 125 therebetween.

The top surface of the layer 113b is partly covered with the mask layer 118b. The top surface of the layer 113w is partly covered with the mask layer 118w. The insulating layer 125 and the insulating layer 127 overlap with part of the top surface of the layer 113b with the mask layer 118b therebetween. The insulating layer 125 and the insulating layer 127 overlap with part of the top surface of the layer 113w with the mask layer 118w therebetween. Note that each of the top surfaces of the layer 113b and the layer 113w is not limited to the top surface of a flat portion overlapping with the top surface of the pixel electrode, and can include the top surfaces of the inclined portion and the flat portion which are positioned on the outer side of the top surface of the pixel electrode.

The side surface and part of the top surface of the layer 113b are covered with at least one of the insulating layer 125, the insulating layer 127, and the mask layer 118b, so that the common layer 114 (or the common electrode 117) can be inhibited from being in contact with the side surfaces of the pixel electrode 111b and the layer 113b. The side surface and part of the top surface of the layer 113w are covered with at least one of the insulating layer 125, the insulating layer 127, and the mask layer 118w, so that the common layer 114 (or the common electrode 117) can be inhibited from being in contact with the side surfaces of the pixel electrode 111w and the layer 113w. Thus, a short circuit between an upper layer and a lower layer included in the light-emitting device can be inhibited.

The insulating layer 127 is provided over the insulating layer 125 so as to fill a depressed portion in which the insulating layer 125 is formed. The insulating layer 127 can overlap with the side surfaces and part of the top surfaces of the layer 113b and the layer 113w with the insulating layer 125 therebetween. The insulating layer 127 preferably covers at least part of the side surface of the insulating layer 125.

The insulating layer 125 and the insulating layer 127 can fill a gap between adjacent island-shaped layers, whereby extreme unevenness of the formation surface of the layers (e.g., the carrier-injection layer and the common electrode) provided over the island-shaped layers can be reduced, and the formation surface can be made flatter. Consequently, the coverage of the carrier-injection layer, the common electrode, and the like can be improved.

The common layer 114 and the common electrode 117 are provided over the layer 113b, the layer 113w, the mask layer 118b, the mask layer 118w, the insulating layer 125, and the insulating layer 127. Before the insulating layer 125 and the insulating layer 127 are provided, a step difference is generated owing to a region where the pixel electrode and the island-shaped EL layer are provided and a region where neither the pixel electrode nor the island-shaped EL layer is provided (a region between the light-emitting devices).

In the display apparatus of one embodiment of the present invention, the insulating layer 125 and the insulating layer 127 can eliminate the step difference, and coverage with the common layer 114 and the common electrode 117 can be improved. Thus, connection defects caused by step disconnection can be inhibited. Alternatively, an increase in electric resistance caused by local thinning of the common electrode 117 due to the step can be suppressed.

The top surface of the insulating layer 127 preferably has a shape with high flatness, but may include a projection portion, a convex surface, a concave surface, or a depressed portion.

As illustrated in FIG. 4B, the common layer 114 and the common electrode 117 can be formed with good coverage by providing the mask layer 118b, the mask layer 118w, the insulating layer 125, and the insulating layer 127. It is also possible to prevent formation of a disconnected portion and a locally thinned portion in the common layer 114 and the common electrode 117.

This can inhibit the common layer 114 and the common electrode 117 between adjacent light-emitting devices from having connection defects due to the disconnected portion and an increased electric resistance due to the locally thinned portion. Thus, the display quality of the display apparatus of one embodiment of the present invention can be improved.

Next, examples of materials of the insulating layer 125 and the insulating layer 127 are described.

The insulating layer 125 can include an inorganic material. As the insulating layer 125, an inorganic insulating film such as an oxide insulating film, a nitride insulating film, an oxynitride insulating film, or a nitride oxide insulating film can be used, for example. The insulating layer 125 is not limited to a single-layer structure, and can have a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferable because it has high selectivity with respect to the EL layer in etching and has a function of protecting the EL layer in forming the insulating layer 127 which is to be described later.

In particular, when an inorganic insulating film such as an aluminum oxide film, a hafnium oxide film, or a silicon oxide film formed by an atomic layer deposition (ALD) method is used as the insulating layer 125, the insulating layer 125 having few pin holes and an excellent function of protecting the EL layer can be formed. The insulating layer 125 may also have a stacked-layer structure of a film formed by an ALD method and a film formed by a sputtering method. The insulating layer 125 may also have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a targeted substance (also referred to as having low permeability). Alternatively, a barrier property refers to a function of capturing or fixing (also referred to as gettering) a targeted substance.

When the insulating layer 125 has a function of a barrier insulating layer or a gettering function, entry of impurities (typically, at least one of water and oxygen) that might diffuse into the light-emitting devices from the outside can be inhibited. With this structure, highly reliable light-emitting devices and a highly reliable display apparatus can be provided.

The same material can be used for the insulating layer 125 and the mask layer 118b. In that case, the boundary between the mask layer 118b and the insulating layer 125 is unclear and thus the mask layer 118b and the insulating layer 125 are sometimes observed as one layer.

The insulating layer 127 provided over the insulating layer 125 has a function of filling extreme unevenness of the insulating layer 125, which is formed between the adjacent light-emitting devices.

As the insulating layer 127, an insulating layer containing an organic material can be suitably used. As the organic material, a photosensitive organic resin is preferably used, and for example, a photosensitive resin composition containing an acrylic resin is used. Note that in this specification and the like, an acrylic resin refers to not only a polymethacrylic acid ester or a methacrylic resin, but also all the acrylic polymer in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like can be used. Alternatively, an organic material such as polyvinyl alcohol (PVA), polyvinylbutyral, polyvinylpyrrolidone, polyethylene glycol, polyglycerin, pullulan, water-soluble cellulose, an alcohol-soluble polyamide resin, or the like can be used for the insulating layer 127. As the photosensitive resin, a photoresist can be used. As the photosensitive organic resin, either a positive-type material or a negative-type material can be used.

As illustrated in FIG. 4B, a coloring layer 137 that functions as a color filter is provided in a region overlapping with the light-emitting device 130b. Since the light-emitting device 130b emits white light, provision of the coloring layer 137 enables the subpixel to emit red light, green light, blue light, or the like. In FIG. 4B, the subpixel B is a subpixel emitting blue light, and thus, a layer that transmits blue light is used as the coloring layer 137. In addition, the subpixel W is a subpixel emitting white light, and thus, the coloring layer 137 is not provided for the subpixel W.

Next, the subpixel B and the region T in the pixel 11 will be described. FIG. 4C illustrates a cross-sectional view along Y1-Y2 of the pixel 11 illustrated in FIG. 4A. The subpixel B can have the same structure as the subpixel B in the pixel 10.

The light-transmitting region T can have a structure in which the components of the light-emitting device except for the insulating layer, the common electrode, and the like with a high transmittance with respect to the light used for image capturing are omitted. FIG. 4C illustrates the structure in which the insulating layer 255a, the insulating layer 255b, the insulating layer 255c, the common layer 114, the common electrode 117, and the protective layer 131 are provided in the light-transmitting region T, and all of them are preferably formed using materials with a high transmittance to visible light or to light with a wavelength range from blue light to red light. To improve the transmittance of the light-transmitting region T, a structure in which one or more of the insulating layer 255a, the insulating layer 255b, the insulating layer 255c, the common layer 114, the common electrode 117, and the protective layer 131 are not provided can be employed.

The protective layer 131 provided over the light-emitting devices 130b and 130w is not limited to a single-layer structure, and can have a stacked-layer structure of two or more layers. Provision of the protective layer 131 can improve the reliability of the light-emitting devices 130b and 130w.

There is no limitation on the conductivity of the protective layer 131. As the protective layer 131, at least one type of an insulating film, a semiconductor film, and a conductive film can be used.

The protective layer 131 including an inorganic film can inhibit deterioration of the light-emitting device by preventing oxidation of the common electrode 117 and inhibiting entry of impurities (e.g., moisture and oxygen) into the light-emitting device and the light-receiving device, for example; thus, the reliability of the display apparatus can be improved.

As the protective layer 131, an inorganic insulating film such as an oxide insulating film, a nitride insulating film, an oxynitride insulating film, or a nitride oxide insulating film can be used, for example. Specific examples of these inorganic insulating films are as listed in the description of the insulating layer 125. In particular, the protective layer 131 preferably includes a nitride insulating film or a nitride oxide insulating film, and further preferably includes a nitride insulating film.

For the protective layer 131, an inorganic film including In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 117. The inorganic film can be an inorganic film that further contains nitrogen.

The protective layer 131 preferably has a high visible-light-transmitting property. ITO, IGZO, and aluminum oxide are preferable because they are each an inorganic material having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (such as water and oxygen) to the EL layer side.

Furthermore, the protective layer 131 can include an organic film. For example, the protective layer 131 can include both an organic film and an inorganic film. Examples of an organic material that can be used for the protective layer 131 include organic insulating materials that can be used for the insulating layer 127.

The protective layer 131 may have a two-layer structure that are formed by different film formation methods. Specifically, the first layer of the protective layer 131 may be formed by an ALD method, and the second layer of the protective layer 131 may be formed by a sputtering method.

As the adhesive layer 122, a variety of curable adhesives such as a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin can be used. An adhesive sheet or the like can be used.

For the substrate 120, glass, quartz, ceramic, sapphire, a resin, a metal, an alloy, a semiconductor, or the like can be used. The substrate through which light from the light-emitting device is extracted is formed using a material that transmits the light. Using a flexible material for the substrate 120 can improve the flexibility of the display apparatus. A polarizing plate can be used as the substrate 120.

The substrate 120 may be formed using polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like. Glass that is thin enough to have flexibility may be used as the substrate 120.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic resin film.

In the case where a film is used for the substrate and the film absorbs water, the shape of the display apparatus might be changed, e.g., creases are generated. Thus, for the substrate, a film with a low water absorption rate is preferably used. For example, the water absorption rate of the film is preferably lower than or equal to 1%, further preferably lower than or equal to 0.1%, still further preferably lower than or equal to 0.01%.

A variety of optical members can be provided on the outer surface of the substrate 120. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film suppressing the attachment of stain, a hard coat film inhibiting generation of a scratch caused by the use, an impact-absorbing layer, or the like may be provided as a surface protective layer on the outer surface of the substrate 120.

For example, a glass layer or a silica layer (SiOₓ layer) is preferably provided as the surface protective layer to inhibit the surface contamination and generation of a scratch. The surface protective layer may be formed using DLC (diamond like carbon), aluminum oxide (AlOₓ), a polyester-based material, a polycarbonate-based material, or the like. For the surface protective layer, a material having a high visible-light transmittance is preferably used. For the surface protective layer, a material with high hardness is preferably used.

In the display apparatus of one embodiment of the present invention, an island-shaped EL layer is provided in each light-emitting device, which can inhibit generation of a leakage current between the subpixels. Thus, it is possible to prevent light emission due to unintended crosstalk, so that a display apparatus with extremely high contrast can be achieved. The insulating layer having a tapered end portion and being provided between adjacent island-shaped EL layers can inhibit generation of step disconnection at the time of forming the common electrode. This can inhibit the common layer and the common electrode from having connection defects due to the disconnected portion. Hence, the display apparatus of one embodiment of the present invention achieves both high resolution and high display quality.

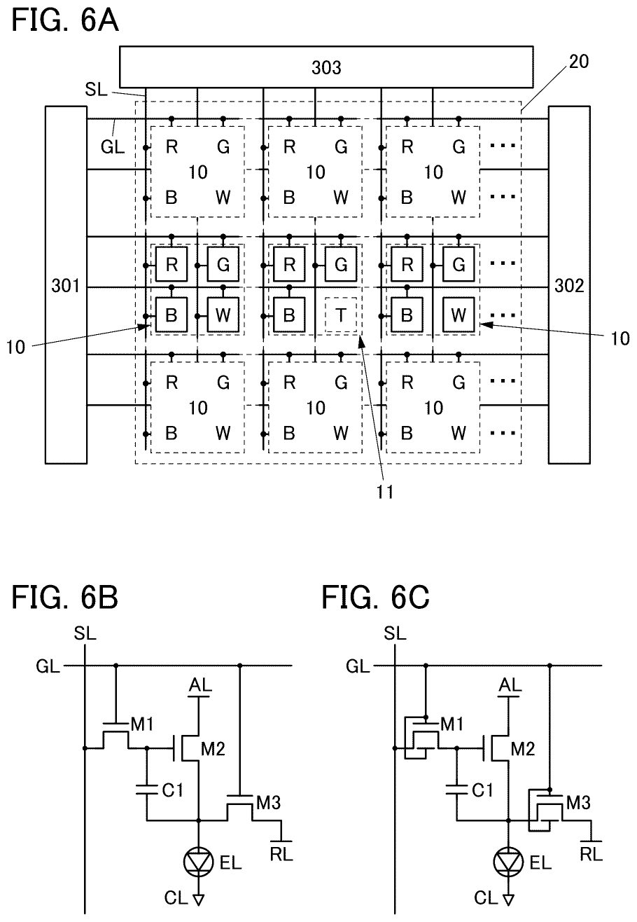

FIG. 6A is a block diagram illustrating a display apparatus of one embodiment of the present invention. The display apparatus includes a pixel array provided in the display portion 20, a driver circuit 301, a driver circuit 302, and a driver circuit 303. The pixel array includes pixels 10 and a pixel 11 arranged in the column direction and the row direction. The pixel 11 is placed so as to be surrounded by the pixels 10.

The driver circuits 301, 302, and 303 are drivers for driving the pixel array. As the driver circuit 301, the driver circuit 302, and the driver circuit 303, a shift register circuit that operates at high speed can be used, for example.

The driver circuits 301 and 302 can have a function of a gate driver and the driver circuit 303 can have a function of a source driver. The driver circuits 301 and 302 are electrically connected to the pixel through a gate line GL. The driver circuit 303 is electrically connected to the pixel through a source line SL.

Although FIG. 6A illustrates an example in which the driver circuits 301 and 302 are provided as gate drivers, the structure in which one of the driver circuit 301 and the driver circuit 302 is provided can also be employed. The driver circuits 301 and 302 are connected to the same gate line GL, however, the driver circuit 301 and the driver circuit 302 can be connected to different gate lines GL. Note that a demultiplexer can be provided between the driver circuit 303 and the pixel.

FIG. 6B illustrates an example of a pixel circuit applicable to the pixel. The pixel circuit includes a transistor M1, a transistor M2, a transistor M3, a capacitor C1, and a light-emitting device EL. The gate line GL and the source line SL are electrically connected to the pixel circuit (see FIG. 6A).

A gate of the transistor M1 is electrically connected to the gate line GL, one of a source and a drain of the transistor MI is electrically connected to the source line SL, and the other of the source and the drain of the transistor MI is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting device EL, the other electrode of the capacitor C1, and one of a source and a drain of the transistor M3. A gate of the transistor M3 is electrically connected to the gate line GL, and the other of the source and the drain of the transistor M3 is electrically connected to a wiring RL. The other electrode of the light-emitting device EL is electrically connected to a wiring CL.

A data potential is supplied to the source line SL. A selection signal is supplied to the gate line GL. The selection signal includes a potential for bringing a transistor into a conducting state and a potential for bringing a transistor into a non-conducting state.

A reset potential is supplied to the wiring RL. An anode potential is supplied to the wiring AL. A cathode potential is supplied to the wiring CL. The anode potential is a potential higher than the cathode potential. The reset potential supplied to the wiring RL can be set such that the potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistor M1 and the transistor M3 function as switches. The transistor M2 functions as a transistor for controlling current flowing through the light-emitting device EL. For example, it can be said that the transistor M1 functions as a selection transistor and the transistor M2 functions as a driving transistor.

Here, a transistor containing a metal oxide in their channel formation region (hereinafter, referred to as an OS transistor) can be used as each of the transistors M1 to M3. Alternatively, a transistor containing silicon (single crystal silicon, polycrystalline silicon, microcrystalline silicon, or amorphous silicon) in their channel formation region (hereinafter, referred to as a Si transistor) can be used as all of the transistors M1 to M3. Alternatively, it is possible to use OS transistors as the transistors M1 and M3 and to use a Si transistor as the transistor M2.

A Si transistor can be used as one or more of a plurality of transistors included in the driver circuits 301, 302, and 303 and an OS transistor can be used as the other transistors. One or more of the driver circuits 301, 302, and 303 can be formed using Si transistors and the other can be formed using OS transistors.

As the OS transistor, a transistor including an oxide semiconductor in its semiconductor layer where a channel is formed can be used. A semiconductor layer preferably contains indium, M (Mis one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, Mis preferably one or more selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Alternatively, it is preferable to use an oxide containing indium, gallium, tin, and zinc.

A transistor containing an oxide semiconductor having a wider band gap and a lower carrier concentration than silicon can achieve an extremely low off-state current. Thus, such a low off-state current enables long-term retention of electric charge accumulated in a capacitor that is connected to the transistor in series. Hence, it is particularly preferable to use transistors containing an oxide semiconductor as each of the transistors M1 and M3 that is connected to the capacitor C1 in series. The use of the transistor containing an oxide semiconductor as each of the transistors M1 and M3 can prevent leakage of electric charge retained in the capacitor C1 through the transistor M1 or M3. Furthermore, since charge retained in the capacitor C1 can be retained for a long time, a still image can be displayed for a long period without rewriting data in the pixel.

Note that although the transistor is illustrated as an n-channel transistor in FIG. 6B, a p-channel transistor can also be used.

A transistor including a pair of gates overlapping with a semiconductor layer therebetween can be used as the transistor included in the pixel circuit.

In the transistor including a pair of gates, the same potential is supplied to the pair of gates electrically connected to each other, whereby the on-state current of the transistor can be increased and the saturation characteristics can be improved. A potential for controlling the threshold voltage of the transistor may also be supplied to one of the pair of gates. Furthermore, when a constant potential is supplied to one of the pair of gates, the stability of the electrical characteristics of the transistor can be improved. For example, one of the gates of the transistor can be electrically connected to a wiring to which a constant potential is supplied. Alternatively, one of the gates of the transistor can be electrically connected to a source or a drain.

The pixel circuit illustrated in FIG. 6C is an example where a transistor including a pair of gates is used as each of the transistors M1 and M3. The pair of gates are electrically connected to each other in each of the transistors M1 and M3. Such a structure makes it possible to shorten the period in which data is written to the pixel circuit.

At least part of this embodiment can be implemented in combination with any of the other embodiments described in this specification as appropriate.

### Embodiment 3

In this embodiment, vertical transistors that can be used in the pixels 10 and 11 and the driver circuits 301, 302, and 303 described in Embodiment 2 will be described. The vertical transistor has a structure that facilitates reduction in size and high-speed operation.

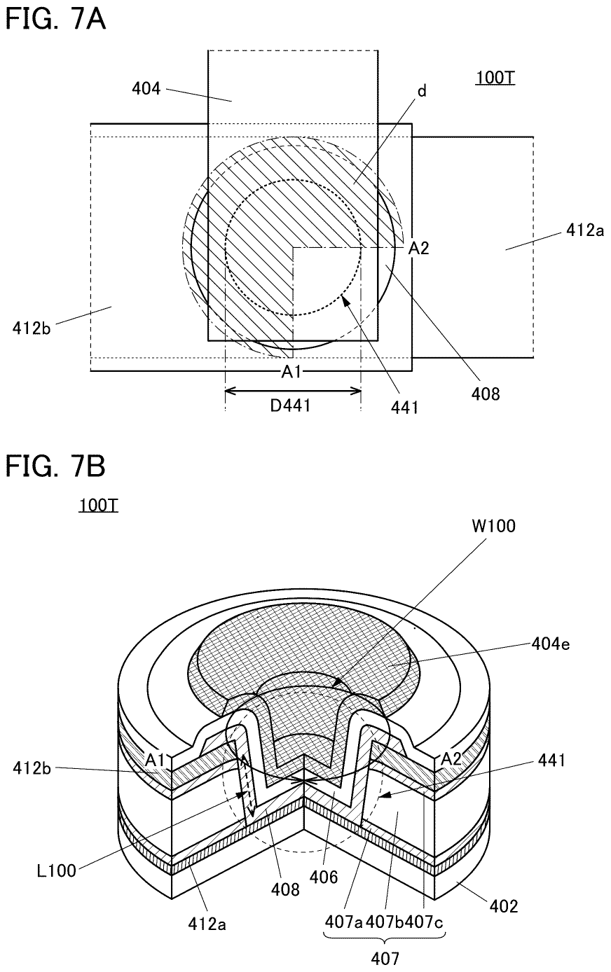

FIG. 7A and FIG. 7B are diagrams illustrating a vertical transistor. FIG. 7A is a top view. FIG. 7B is a cross-sectional perspective view along A1-A2 in the depth direction of a region d illustrated in FIG. 7A. Note that for simplification, some components are not illustrated in FIG. 7A and FIG. 7B.

A transistor 100T, which is a vertical transistor, can be provided over a substrate 402. The transistor 100T includes a conductive layer 404, a conductive layer 404e, an insulating layer 406, a semiconductor layer 408, a conductive layer 412a, and a conductive layer 412b. The conductive layer 404 is a gate wiring electrically connected to the conductive layer 404e functioning as a gate electrode. Part of the insulating layer 406 functions as a gate insulating layer. The conductive layer 412a functions as one of a source electrode and a drain electrode. The conductive layer 412b functions as the other of the source electrode and the drain electrode.

The conductive layer 412a is provided over the substrate 402, an insulating layer 407 is provided over the conductive layer 412a, and the conductive layer 412b is provided over the insulating layer 407. The insulating layer 407 includes a region interposed between the conductive layer 412a and the conductive layer 412b. The conductive layer 412a includes a region overlapping with the conductive layer 412b with the insulating layer 407 therebetween. An opening 441 reaching the conductive layer 412a is provided in the insulating layer 407 and the conductive layer 412b.

Although the conductive layer 412a and the conductive layer 412b each having a single-layer structure are illustrated in FIG. 7B, one embodiment of the present invention is not limited thereto. The conductive layer 412a and the conductive layer 412b can each have a stacked-layer structure.

The top surface shape of the opening 441 can be a circle or an ellipse, for example. When the top surface shape of the opening 441 is a circle, the opening 441 can be formed with high processing accuracy and the opening 441 having a minute size can be formed. Note that the top surface shape of the opening 441 may also be a polygon such as a triangle, a quadrilateral (including a rectangle, a rhombus, and a square), or a pentagon, or the polygon with rounded corners. The opening 441 can be formed using a resist mask, for example.

The semiconductor layer 408 is provided to cover the opening 441. The semiconductor layer 408 includes a region in contact with a top surface and a side surface of the conductive layer 412b, a side surface of the insulating layer 407, and a top surface of the conductive layer 412a. The semiconductor layer 408 is electrically connected to the conductive layer 412a through the opening 441. The semiconductor layer 408 has a shape along the shapes of the top surface and the side surface of the conductive layer 412b, the side surface of the insulating layer 407, and the top surface of the conductive layer 412a.

In the semiconductor layer 408 provided along the side surface of the insulating layer 407, between the source electrode and the drain electrode, the entire region overlapping with the gate electrode with the gate insulating layer therebetween functions as a channel formation region. In the semiconductor layer 408, a region in contact with the source electrode functions as a source region, and a region in contact with the drain electrode functions as a drain region.

Although the semiconductor layer 408 has a single-layer structure in FIG. 7B and the like, one embodiment of the present invention is not limited thereto. The semiconductor layer 408 can have a stacked structure of two or more layers.

The insulating layer 406 functioning as the gate insulating layer of the transistor 100T is provided over the semiconductor layer 408, the conductive layer 412b, and the insulating layer 407 to cover a depressed portion originating from the opening 441.

The conductive layer 404e of the transistor 100T is provided over the insulating layer 406 to cover the depressed portion originating from the opening 441. Here, an insulating layer (not illustrated) is preferably provided over the conductive layer 404e and the insulating layer 406. An opening reaching the conductive layer 404e is formed in the insulating layer and the conductive layer 404 functioning as a gate line is electrically connected to the conductive layer 404e in the opening.

The conductive layer 404e includes a region overlapping with the semiconductor layer 408 with the insulating layer 406 therebetween in the opening 441. The conductive layer 404e also includes a region overlapping with the conductive layer 412a and a region overlapping with the conductive layer 412b with the insulating layer 406 and the semiconductor layer 408 therebetween. The conductive layer 404e preferably covers an end portion of the conductive layer 412b on the opening 441 side.

The transistor 100T is what is called a top-gate transistor including the gate electrode above the semiconductor layer 408. Furthermore, since a bottom surface of the semiconductor layer 408 is in contact with the source electrode or the drain electrode, the transistor 100T can be referred to as a TGBC (Top Gate Bottom Contact) transistor.

The conductive layer 412a, the conductive layer 412b, and the conductive layer 404 can function as wirings, and the transistor 100T can be provided in a region where these wirings overlap with each other. That is, the areas occupied by the transistor 100T and the wirings can be reduced in the circuit including the transistor 100T and the wirings. This can reduce the area occupied by the circuit.

In the transistor of one embodiment of the present invention, the conductive layer 412a, the conductive layer 412b, and the conductive layer 404 functioning as wirings can be provided by processing different conductive films. Thus, any one of the conductive layers can be provided to overlap with at least one of the other conductive layers, leading to high layout flexibility and a reduction in the area occupied by the circuit.

Next, the channel length and the channel width of the transistor 100T will be described. In the semiconductor layer 408, a region in contact with the conductive layer 412a functions as one of the source region and the drain region, a region in contact with the conductive layer 412b functions as the other of the source region and the drain region, and a region between the source region and the drain region functions as the channel formation region.

The channel length of the transistor 100T is the distance between the source region and the drain region. In FIG. 7B, a channel length L100 of the transistor 100T is indicated by a dashed double-headed arrow. In the cross-sectional view, the channel length L100 is the distance between an end portion of the region where the semiconductor layer 408 is in contact with the conductive layer 412a and an end portion of the region where the semiconductor layer 408 is in contact with the conductive layer 412b.

That is, the channel length L100 is determined by the thickness of the insulating layer 407 and the angle formed by the side surface of the insulating layer 407 on the opening 441 side and the top surface of the conductive layer 412a, and is not affected by the performance of a light-exposure apparatus used for manufacturing the transistor. Thus, the channel length L100 can be a value smaller than that of the resolution limit of a light-exposure apparatus, which enables a transistor having a minute size.

The reduction in the channel length L100 can increase the on-state current of the transistor 100T. With use of the transistor 100T, a circuit capable of high-speed operation can be manufactured. Furthermore, the transistor can be downsized, which enables a reduction in the area occupied by the circuit.

Although FIG. 7B and the like illustrate the structure in which the side surface of the insulating layer 407 on the opening 441 side is linear in the cross-sectional view, one embodiment of the present invention is not limited thereto. In a cross-sectional view, the side surface of the insulating layer 407 on the opening 441 side can be curved. Alternatively, the side surface can include both a linear region and a curved region.

The channel width of the transistor 100T is the width of the source region or the width of the drain region in a direction orthogonal to the channel length direction. That is, the channel width is a width of a region where the semiconductor layer 408 is in contact with the conductive layer 412a or a width of a region where the semiconductor layer 408 is in contact with the conductive layer 412b in the direction orthogonal to the channel length direction. Here, the channel width of the transistor 100T is described as the width of the region where the semiconductor layer 408 is in contact with the conductive layer 412b in the direction orthogonal to the channel length direction. In FIG. 7B, a channel width W100 of the transistor 100T is indicated by a solid double-headed arrow. In the top view, the channel width W100 is the length of the end portion of the bottom surface of the conductive layer 412b on the opening 441 side.

The channel width W100 is determined by the top surface shape of the opening 441. Note that in the case where the top surface shape of the opening 441 is a circle, the channel width W100 can be calculated to be “D441×π” assuming that the diameter of the opening 441 is D441 and the thickness of the conductive layer 412b is negligible.

In other words, it can be said that the transistor 100T has a large channel width with respect to its occupation area. The transistor 100T with the large channel width W100 can have a high on-state current and thus a circuit capable of high-speed operation can be manufactured.

Components included in the transistor 100T of this embodiment will be described below.

### Components of Transistor

### [Semiconductor Layer 408]

There is no particular limitation on a semiconductor material that can be used for the semiconductor layer 408. For example, a single-element semiconductor or a compound semiconductor can be used. As the single-element semiconductor, silicon or germanium can be used, for example. Examples of the compound semiconductor include gallium arsenide and silicon germanium. As the compound semiconductor, an organic substance having semiconductor characteristics or a metal oxide having semiconductor characteristics (also referred to as an oxide semiconductor) can be used. These semiconductor materials can contain impurities as dopants.

There is no particular limitation on the crystallinity of a semiconductor material used for the semiconductor layer 408, and any of an amorphous semiconductor and a semiconductor having crystallinity (a single crystal semiconductor, a polycrystalline semiconductor, a microcrystalline semiconductor, or a semiconductor partly including crystal regions) may be used. A semiconductor having crystallinity is preferably used, in which case degradation of the transistor characteristics can be inhibited.

The semiconductor layer 408 preferably includes a metal oxide (an oxide semiconductor). Examples of the metal oxide that can be used for the semiconductor layer 408 include indium oxide, gallium oxide, and zinc oxide. The metal oxide preferably contains at least indium (In) or zinc (Zn). The metal oxide preferably contains two or three kinds selected from indium, an element M, and zinc. The element M is one or more kinds selected from gallium, aluminum, silicon, boron, yttrium, tin, antimony, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin. The element M is further preferably gallium.

For the semiconductor layer 408, for example, any of indium oxide, indium gallium oxide (In—Ga oxide), indium zinc oxide (In—Zn oxide), indium tin oxide (In—Sn oxide), indium titanium oxide (In—Ti oxide), gallium zinc oxide (Ga—Zn oxide), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), and indium gallium aluminum zinc oxide (In—Ga—Al—Zn oxide, also referred to as IGAZO or IAGZO) can be used. Alternatively, indium tin oxide containing silicon, or the like can also be used.

Here, the composition of the metal oxide included in the semiconductor layer 408 greatly affects the electrical characteristics and reliability of the transistor 100T. For example, by increasing the proportion of the number of indium atoms in the total number of atoms of all the metal elements contained in the metal oxide, a transistor having a high on-state current can be provided.

In the case of using In-Zn oxide for the semiconductor layer 408, a metal oxide in which the atomic proportion of indium is higher than or equal to the atomic proportion of zinc is preferably used. For example, it is possible to use a metal oxide in which the atomic ratio of metal elements is In:Zn=1:1, In:Zn=2:1, In:Zn=3:1, In:Zn=4:1, In:Zn=5:1, In:Zn=7:1, or In:Zn=10:1, or in the neighborhood thereof.

In the case of using In-Sn oxide for the semiconductor layer 408, a metal oxide in which the atomic proportion of indium is higher than or equal to the atomic proportion of tin is preferably used. For example, it is possible to use a metal oxide in which the atomic ratio of metal elements is In:Sn=1:1, In:Sn=2:1, In:Sn=3:1, In:Sn=4:1, In:Sn=5:1, In:Sn=7:1, or In:Sn=10:1, or in the neighborhood thereof.

In the case of using In-Sn-Zn oxide for the semiconductor layer 408, a metal oxide in which the atomic proportion of indium is higher than the atomic proportion of tin can be used. It is further preferable to use a metal oxide in which the atomic proportion of zinc is higher than the atomic proportion of tin. For example, it is possible to use a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, or In:Sn:Zn=40:1:10, or in the neighborhood thereof.

In the case of using In-Al-Zn oxide for the semiconductor layer 408, a metal oxide in which the atomic proportion of indium is higher than the atomic proportion of aluminum can be used. It is further preferable to use a metal oxide in which the atomic proportion of zinc is higher than the atomic proportion of aluminum. For example, it is possible to use a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, or In:Al:Zn=40:1:10, or in the neighborhood thereof.

In the case of using In-Ga-Zn oxide for the semiconductor layer 408, a metal oxide in which the atomic proportion of indium with respect to the total number of atoms of all the contained metal elements is higher than the atomic proportion of gallium can be used. It is further preferable to use a metal oxide in which the atomic proportion of zinc atoms is higher than the atomic proportion of gallium atoms. For example, it is possible to use a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or in the neighborhood thereof for the semiconductor layer 408.

In the case of using In-M-Zn oxide for the semiconductor layer 408, a metal oxide in which the atomic proportion of indium in the total number of atoms of all the contained metal elements is higher than the atomic proportion of element M can be used. It is further preferable to use a metal oxide in which the atomic proportion of zinc is higher than the atomic proportion of the element M. For example, a metal oxide having any of the following atomic ratios of metal elements can be used for the semiconductor layer 408: In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, and the neighborhood thereof.

A metal oxide with a higher indium content percentage enables a transistor to have a higher on-state current. By using such a transistor as a transistor requiring a high on-state current, a circuit having excellent electrical characteristics can be formed.

As an analysis method of the composition of a metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used. Alternatively, these methods may also be combined for the analysis. An element with lower content percentages might show discrepancy between the actual content percentage and the content percentage obtained by analysis due to the analysis accuracy. In the case where the content percentage of the element M is low, for example, the content percentage of the element M obtained by analysis may be lower than the actual content percentage.

A composition in the neighborhood in this specification and the like includes the range of ±30% of an intended atomic ratio. For example, when the atomic ratio is described as In:M:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. When the atomic ratio is described as In:M:Zn=5:1:6 or a composition in the neighborhood thereof, the case is included where the atomic ratio of the element Mis greater than 0.1 and less than or equal to 2 and the atomic ratio of zinc is greater than or equal to 5 and less than or equal to 7 with the atomic ratio of indium being 5. When the atomic ratio is described as In:M:Zn=1:1:1 or a composition in the neighborhood thereof, the case is included where the atomic ratio of the element M is greater than 0.1 and less than or equal to 2 and the atomic ratio of zinc is greater than 0.1 and less than or equal to 2 with the atomic ratio of indium being 1.

A sputtering method or an atomic layer deposition (ALD) method can be suitably used to form the metal oxide. Note that in the case where the metal oxide is formed by a sputtering method, the atomic ratio of a target may be different from the atomic ratio of the metal oxide. In particular, the atomic proportion of zinc in the metal oxide is lower than the atomic proportion of zinc in the target in some cases. Specifically, the atomic proportion of zinc contained in the metal oxide may be approximately 40% to 90% of the atomic proportion of zinc contained in the target.

The semiconductor layer 408 may also have a stacked-layer structure including two or more metal oxide layers. The two or more metal oxide layers included in the semiconductor layer 408 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer 408 can have different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

It is preferable to use a metal oxide layer having crystallinity as the semiconductor layer 408. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer 408, the density of defect states in the semiconductor layer 408 can be reduced, which enables the transistor to have high reliability.

The higher the crystallinity of the metal oxide layer used as the semiconductor layer 408 is, the lower the density of defect states in the semiconductor layer 408 can be. By contrast, the use of a metal oxide layer having low crystallinity achieves a transistor through which a large amount of current can flow.

The semiconductor layer 408 may also have a stacked-layer structure of two or more metal oxide layers having different crystallinities. For example, a stacked-layer structure of the first metal oxide layer and the second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer 408 may have the same composition or substantially the same compositions. Employing a stacked-layer structure of metal oxide layers having the same composition can reduce the manufacturing cost because, for example, the metal oxide layers can be formed using the same sputtering target. For example, with use of the same sputtering target and different oxygen flow rate ratios, a stacked-layer structure of two or more metal oxide layers having different crystallinities can be formed. The two or more metal oxide layers included in the semiconductor layer 408 can have different compositions.

When an oxide semiconductor is used for the semiconductor layer 408, the carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

A transistor including an oxide semiconductor (hereinafter referred to as an OS transistor) has much higher field-effect mobility than a transistor including amorphous silicon. In addition, the OS transistor has an extremely low leakage current between a source and a drain in an off state (hereinafter, also referred to as off-state current), and electric charge accumulated in a capacitor that is connected in series to the transistor can be retained for a long period. Furthermore, the power consumption of the semiconductor apparatus can be reduced with the OS transistor.

### Insulating Layer 407

In the case where an oxide semiconductor is used for the semiconductor layer 408, an inorganic insulating material can be suitably used for the insulating layer 407 (an insulating layer 407a, an insulating layer 407b, and an insulating layer 407c). Note that the insulating layer 407 can have a stacked-layer structure of an inorganic insulating material and an organic insulating material.

As the inorganic insulating material, one or more of an oxide, an oxynitride, a nitride oxide, and a nitride can be used. For the insulating layer 407, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

In this specification and the like, an oxynitride refers to a material that includes more oxygen than nitrogen in its composition. A nitride oxide refers to a material that includes more nitrogen than oxygen in its composition. For example, silicon oxynitride refers to a material that contains more oxygen than nitrogen in its composition, and silicon nitride oxide refers to a material that contains more nitrogen than oxygen in its composition.

It is preferable to use an oxide or an oxynitride for the insulating layer 407b. A film from which oxygen is released by heating is preferably used as the insulating layer 407b. For example, silicon oxide or silicon oxynitride can be suitably used for the insulating layer 407b.

When oxygen is released from the insulating layer 407b, oxygen can be supplied from the insulating layer407b to the semiconductor layer 408. Supplying oxygen from the insulating layer 407b to the semiconductor layer 408, particularly to the channel formation region in the semiconductor layer 408, can reduce the amount of oxygen vacancy (Vo) and VoH (defect in which hydrogen enters oxygen vacancy) in the semiconductor layer 408, so that a highly reliable transistor having favorable electrical characteristics can be obtained. The insulating layer 407b preferably has a high oxygen diffusion coefficient. When the insulating layer 407b has a high oxygen diffusion coefficient, oxygen is easily diffused in the insulating layer 407b, so that oxygen can be efficiently supplied from the insulating layer 407b to the semiconductor layer 408. Examples of treatment for supplying oxygen to the semiconductor layer 408 include heat treatment in an oxygen-containing atmosphere and plasma treatment in an oxygen-containing atmosphere.

It is preferable that the amount of oxygen vacancy (Vo) and VoH be small in the channel formation region of the transistor 100T. Particularly in the case where the channel length L100 is short, oxygen vacancy (Vo) and VoH in the channel formation region greatly affect electrical characteristics and reliability. For example, diffusion of VoH from the source region or the drain region into the channel formation region increases the carrier concentration in the channel formation region, which might cause a change in the threshold voltage or a reduction in the reliability in the transistor 100T. As the channel length L100 of the transistor 100T is shorter, such diffusion of VoH greatly affects electrical characteristics and reliability. Supplying oxygen from the insulating layer 407b to the semiconductor layer 408, particularly to the channel formation region in the semiconductor layer 408, can reduce the amount of oxygen vacancy (Vo) and VoH. Thus, the transistor with a short channel length can have favorable electrical characteristics and high reliability.

The insulating layer 407a and the insulating layer 407c are preferably less likely to transmit oxygen. The insulating layer 407a and the insulating layer 407c function as blocking films that inhibit release of oxygen from the insulating layer 407b. Moreover, the insulating layer 407a and the insulating layer 407c are preferably less likely to transmit hydrogen. The insulating layer 407a and the insulating layer 407c function as blocking films that inhibit diffusion of hydrogen into the semiconductor layer 408 from the outside of the transistor through the insulating layer 407. The insulating layer 407a and the insulating layer 407c preferably have high film densities. The insulating layer 407a and the insulating layer 407c having high film densities can have a high blocking property against oxygen and hydrogen. The film densities of the insulating layer 407a and the insulating layer 407c are preferably higher than the film density of the insulating layer 407b. In the case where silicon oxide or silicon oxynitride is used for the insulating layer 407b, silicon nitride, silicon nitride oxide, or aluminum oxide can be suitably used for each of the insulating layer 407a and the insulating layer 407c, for example. The insulating layer 407a and the insulating layer 407c each preferably include a region containing more nitrogen than the insulating layer 407b. For example, a material containing more nitrogen than the insulating layer 407b can be used for each of the insulating layer 407a and the insulating layer 407c. A nitride or a nitride oxide is preferably used for each of the insulating layer 407a and the insulating layer 407c. For example, silicon nitride or silicon nitride oxide can be suitably used for each of the insulating layer 407a and the insulating layer 407c.

When oxygen contained in the insulating layer 407b is diffused upward from a region of the insulating layer 407b that is not in contact with the semiconductor layer 408 (e.g., a top surface of the insulating layer 407b), the amount of oxygen supplied from the insulating layer 407b to the semiconductor layer 408 might be reduced. Provision of the insulating layer 407c over the insulating layer 407b can inhibit diffusion of oxygen contained in the insulating layer 407b from the region of the insulating layer 407 that is not in contact with the semiconductor layer 408. Similarly, provision of the insulating layer 407a under the insulating layer 407b can inhibit downward diffusion of oxygen from the region of the insulating layer 407 that is not in contact with the semiconductor layer 408. Accordingly, the amount of oxygen supplied from the insulating layer 407b to the semiconductor layer 408 is increased, whereby the amount of oxygen vacancy (Vo) and VoH in the semiconductor layer 408 can be reduced. Consequently, a transistor with favorable electrical characteristics and high reliability can be obtained.

The conductive layer 412a and the conductive layer 412b are oxidized by oxygen contained in the insulating layer 407b and have high resistance in some cases. Moreover, when the conductive layer 412a and the conductive layer 412b are oxidized by oxygen contained in the insulating layer 407b, the amount of oxygen supplied from the insulating layer 407b to the semiconductor layer 408 might be reduced. Provision of the insulating layer 407a between the insulating layer 407b and the conductive layer 412a can inhibit the conductive layer 412a from being oxidized and having high resistance. Similarly, provision of the insulating layer 407c between the insulating layer 407b and the conductive layer 412b can inhibit the conductive layer 412b from being oxidized and having high resistance. In addition, the amount of oxygen supplied from the insulating layer 407b to the semiconductor layer 408 is increased and the amount of oxygen vacancy (Vo) and VoH in the semiconductor layer 408 can be reduced, whereby the transistor can have favorable electric characteristics and high reliability.

Hydrogen diffused in the semiconductor layer 408 reacts with an oxygen atom contained in an oxide semiconductor to be water, and thus sometimes forms oxygen vacancy (Vo). Furthermore, VoH is formed and the carrier concentration is increased in some cases. Provision of the insulating layer 407a and the insulating layer 407c can reduce the amount of oxygen vacancy (Vo) and VoH in the semiconductor layer 408, whereby the transistor can have favorable electric characteristics and high reliability.

The insulating layer 407a and the insulating layer 407c preferably have thicknesses with which the insulating layers function as blocking films against oxygen and hydrogen. When the insulating layer 407a and the insulating layer 407c are thin, the function of a blocking film might deteriorate. Meanwhile, when the insulating layer 407a and the insulating layer 407c are thick, a region where the semiconductor layer 408 is in contact with the insulating layer 407b is narrowed and the amount of oxygen supplied from the insulating layer 407b to the semiconductor layer 408 might be reduced. The insulating layer 407a and the insulating layer 407c may each be thinner than the insulating layer 407b.

In the transistor 100T, oxygen is supplied from the insulating layer 407 to the semiconductor layer 408, whereby the amount of oxygen vacancy (Vo) and VoH in the channel formation region is reduced. Consequently, a transistor with favorable electrical characteristics and high reliability can be obtained.

Note that one or both of the insulating layer 407a and the insulating layer 407c are not necessarily provided.

### Conductive layer 412a, Conductive Layer 412b, and Conductive Layer 404e

The conductive layer 412a, the conductive layer 412b, and the conductive layer 404e functioning as a source electrode, a drain electrode, and a gate electrode can each be formed using one or more of chromium, copper, aluminum, gold, silver, zinc, tantalum, titanium, tungsten, manganese, nickel, iron, cobalt, molybdenum, and niobium; or an alloy including one or more of these metals as its components. For each of the conductive layer 412a, the conductive layer 412b, and the conductive layer 404e, a conductive material with low resistance that contains one or more of copper, silver, gold, and aluminum can be suitably used. Copper or aluminum is particularly preferable because of its high mass-productivity.

As the conductive layer 412a, the conductive layer 412b, and the conductive layer 404e, metal oxide films (also referred to as an oxide conductor (OC)) can be used. Examples of the oxide conductor include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, an oxide conductor will be described. For example, when an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide that has become a conductor can be referred to as an oxide conductor.

Each of the conductive layer 412a, the conductive layer 412b, and the conductive layer 404e may also have a stacked-layer structure of a conductive film containing the oxide conductor (the metal oxide) and a conductive film containing a metal or an alloy. The use of the conductive film including a metal or an alloy can reduce the wiring resistance.

A Cu—X alloy film (X is Mn, Ni, Cr, Fe, Co, Mo, Ta, or Ti) may also be used for each of the conductive layer 412a, the conductive layer 412b, and the conductive layer 404e. By employing a Cu—X alloy film, a wet etching process can be used in the processing, enabling the manufacturing cost savings.

Note that the same material can be used for each of the conductive layer 412a, the conductive layer 412b, and the conductive layer 404e. Alternatively, different materials can be used for the conductive layer 412a, the conductive layer 412b, and the conductive layer 404e.

Here, the conductive layer 412a and the conductive layer 412b will be described in detail with use of a structure in which a metal oxide is used for the semiconductor layer 408 as an example.

When an oxide semiconductor is used for the semiconductor layer 408, the conductive layer 412a and the conductive layer 412b are oxidized by oxygen contained in the semiconductor layer 408 and have high resistance in some cases. The conductive layer 412a and the conductive layer 412b are oxidized by oxygen contained in the insulating layer 407b and have high resistance in some cases. Moreover, when the conductive layer 412a and the conductive layer 412b are oxidized by oxygen contained in the semiconductor layer 408, the amount of oxygen vacancy (Vo) in the semiconductor layer 408 is increased in some cases. When the conductive layer 412a and the conductive layer 412b are oxidized by oxygen contained in the insulating layer 407b, the amount of oxygen supplied from the insulating layer 407b to the semiconductor layer 408 might be reduced.

A material that is less likely to be oxidized is preferably used for each of the conductive layer 412a and the conductive layer 412b. An oxide conductor is preferably used for each of the conductive layer 412a and the conductive layer 412b. For example, In—Sn oxide (ITO) or In—Sn—Si oxide (ITSO) can be suitably used. An nitride conductor may also be used for the conductive layer 412a. Examples of the nitride conductor include tantalum nitride and titanium nitride. The conductive layer 412a can have a stacked-layer structure of the above-described materials.

The conductive layer 412a and the conductive layer 412b each containing a material that is less likely to be oxidized can be inhibited from being oxidized by oxygen contained in the semiconductor layer 408 or oxygen contained in the insulating layer 407b and having high resistance. Furthermore, it is possible to increase the amount of oxygen supplied from the insulating layer 407b to the semiconductor layer 408 while an increase in the amount of oxygen vacancy (Vo) in the semiconductor layer 408 is inhibited. Accordingly, the amount of oxygen vacancy (Vo) and VoH in the semiconductor layer 408 can be reduced, whereby the transistor can have favorable electric characteristics and high reliability.

Note that the same material can be used for each of the conductive layer 412a and the conductive layer 412b. Alternatively, different materials can also be used for the conductive layer 412a and the conductive layer 412b.

The conductive layer 412b has a region in contact with the transistor 100T. When a material that is less likely to be oxidized is used for the conductive layer 412b, the amount of oxygen vacancy (Vo) and VoH in the semiconductor layer 408 can be reduced.

As described above, a material that is less likely to be oxidized is preferably used for each of the conductive layer 412a and the conductive layer 412b in contact with the semiconductor layer 408. However, the use of a material that is less likely to be oxidized might increase resistance. The conductive layer 412a and the conductive layer 412b function as wirings and thus preferably have low resistance. Thus, the conductive layer 412a and the conductive layer 412b can each be a stack of a material that is less likely to be oxidized and a material with low resistance, and the material that is less likely to be oxidized can be in contact with the semiconductor layer 408. With such a structure, the resistance of the conductive layer 412a and the conductive layer 412b can be reduced. Furthermore, the amount of oxygen vacancy (Vo) and VoH in the semiconductor layer 408 can be reduced, whereby the transistor can have favorable electric characteristics and high reliability.

As the material that is less likely to be oxidized, one or more of an oxide conductor and a nitride conductor can be suitably used, for example. As the material with low resistance, one or more of copper, aluminum, titanium, tungsten, and molybdenum or an alloy containing one or more of these metals as its components can be suitably used, for example.

### Insulating Layer 406

The insulating layer 406 functioning as the gate insulating layer preferably has low defect density. With the insulating layer 406 having low defect density, the transistor can have favorable electrical characteristics. In addition, the insulating layer 406 preferably has high withstand voltage. With the insulating layer 406 having high withstand voltage, the transistor can have high reliability.

For the insulating layer 406, one or more of an insulating oxide, an insulating oxynitride, an insulating nitride oxide, and an insulating nitride can be used, for example. For the insulating layer 406, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and Ga-Zn oxide can be used. The insulating layer 406 is not limited to a single-layer structure, and can have a stacked-layer structure. The insulating layer 406 may have a stacked-layer structure of an oxide and a nitride, for example.

A miniaturized transistor including a thin gate insulating layer may have a high leakage current. When a high dielectric constant material (also referred to as a high-k material) is used for the gate insulating layer, the voltage at the time of operation of the transistor can be reduced while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 406 itself is preferably small. With the insulating layer 406 from which a small amount of impurities is released, diffusion of impurities into the semiconductor layer 408 is inhibited, and the transistor can have favorable electrical characteristics and high reliability.

Here, the insulating layer 406 will be described in detail with use of a structure in which a metal oxide is used for the semiconductor layer 408 as an example.

An oxide is preferably used for, at least, the side of the insulating layer 406 being in contact with the semiconductor layer 408 in order to improve the interfacial properties with the semiconductor layer 408. For example, one or more of silicon oxide and silicon oxynitride can be suitably used for the insulating layer 406. A film from which oxygen is released by heating is further preferably used for the insulating layer 406.

The insulating layer 406 can also have a stacked-layer structure. The insulating layer 406 can have a stacked-layer structure of an oxide film on the side in contact with the semiconductor layer 408 and a nitride film on the side in contact with the conductive layer 404e. For example, one or more of silicon oxide and silicon oxynitride can be suitably used for the oxide film. Silicon nitride can be suitably used for the nitride film.

### Substrate 402

Although there is no particular limitation on a material of the substrate 402, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may also be used as the substrate 402. Alternatively, any of these substrates over which a semiconductor element is provided may also be used as the substrate 402. Note that the shape of the semiconductor substrate and an insulating substrate may also be a circular shape or a shape with corners.

A flexible substrate may be used as the substrate 402, and the transistor 100T and the like may also be formed directly on the flexible substrate. Alternatively, a separation layer may also be provided between the substrate 402 and the transistor 100T and the like. The separation layer can be used when part or the whole of a semiconductor apparatus completed thereover is separated from the substrate 402 and transferred onto another substrate. In that case, the transistor 100T and the like can be transferred to a substrate having low heat resistance or a flexible substrate as well.

The above is the description of the components of the transistor 100T.

At least part of this embodiment can be implemented in combination with any of the other embodiments described in this specification as appropriate.

### Embodiment 4

In this embodiment, a display apparatus of one embodiment of the present invention is described.

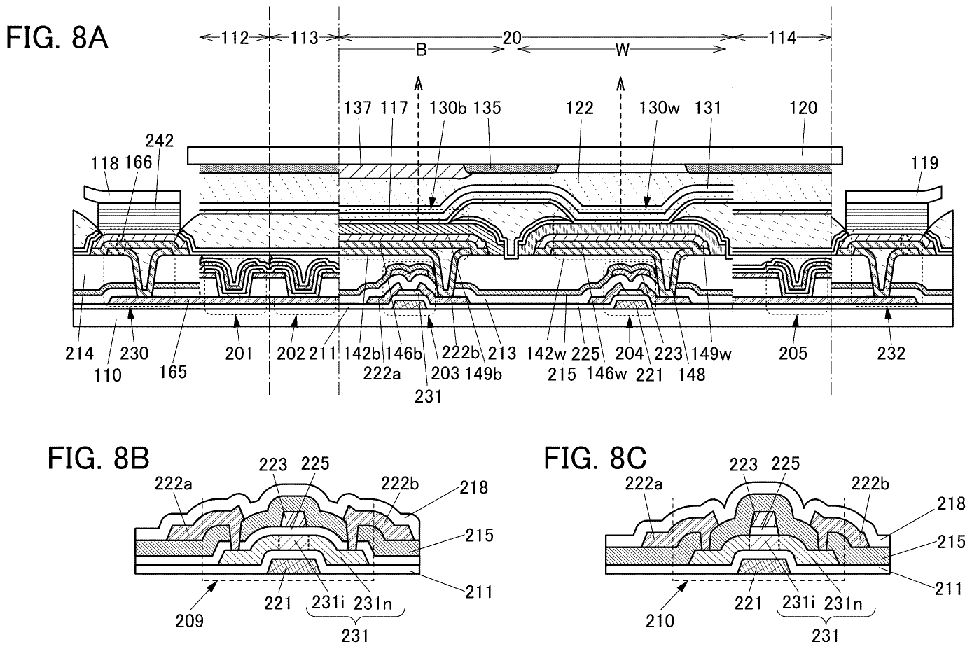

FIG. 8A is a cross-sectional view of the display apparatus that is one embodiment of the present invention.

FIG. 8A illustrates an example of cross sections of part of a region including the driver circuit 301, part of a region including the driver circuit 302, part of a region including the display portion 20, and part of a region including the driver circuit 303 in the display apparatus illustrated in FIG. 6A. In the display portion 20, the pixel 10 including the subpixel B emitting blue light and the subpixel W emitting white light is illustrated as an example.

The display apparatus illustrated in FIG. 8A includes a transistor 201, a transistor 202, a transistor 203, a transistor 204, a transistor 205, the light-emitting device 130b included in the subpixel B, the light-emitting device 130w included in the subpixel W, and the like between a substrate 110 and the substrate 120.

The light-emitting device 130b includes a conductive layer 142b, a conductive layer 146b over the conductive layer 142b, and a conductive layer 149b over the conductive layer 146b. All of the conductive layers 142b, 146b, and 149b can be referred to as pixel electrodes, or one or two of them can be referred to as pixel electrodes.

The light-emitting device 130w includes a conductive layer 142w, a conductive layer 146w over the conductive layer 142w, and a conductive layer 149w over the conductive layer 146w.

The conductive layer 142b is connected to a conductive layer 222b included in the transistor 203 through an opening provided in an insulating layer 214. For example, a conductive layer functioning as a reflective electrode can be used as the conductive layer 142b and the conductive layer 146b, and a conductive layer functioning as a transparent electrode can be used as the conductive layer 149b.

The conductive layers 142b and 142w each have a depressed portion covering the opening provided in the insulating layer 214. A layer 148 is embedded in each of the depressed portions.

The layer 148 has a planarization function for the depressed portions of the conductive layers 142b and 142w. The conductive layers 146b and 146w electrically connected to the conductive layers 142b and 142w, respectively, are provided over the conductive layers 142b and 142w and the layer 148. Thus, a region overlapping with the depressed portion of the conductive layers 142b and 142w can also be used as a light-emitting region, increasing the aperture ratio of the pixel.

Not only an insulating layer but also a conductor layer can be used as the layer 148. Any of a variety of inorganic insulating materials, organic insulating materials, and conductive materials can be used for the layer 148 as appropriate. Specifically, the layer 148 is preferably formed using an insulating material and is particularly preferably formed using an organic insulating material.

The protective layer 131 is provided over the light-emitting devices 130b and 130w. The adhesive layer 122 is provided between the protective layer 131 and the substrate 120.

The display apparatus has a top-emission structure. Light from the light-emitting device is emitted toward the substrate 120 side. For the substrate 120, a material having a high visible-light transmittance is preferably used. The pixel electrode includes a material that reflects visible light, and a counter electrode (the common electrode 117) includes a material that transmits visible light.

The transistors 201 to 205 are formed over the substrate 110. The transistor 203 and the transistor 204 can be manufactured using the same material in the same step. The transistor 201, the transistor 202, and the transistor 205 can be manufactured using the same material in the same step.

Transistors suitable for high-speed operation are preferably used for the driver circuits 301, 302, and 303, and FIG. 8A illustrates an example in which a vertical transistor is used as each of the transistor 201, the transistor 202, and the transistor 205. Embodiment 3 can be referred to for the details of the vertical transistor.

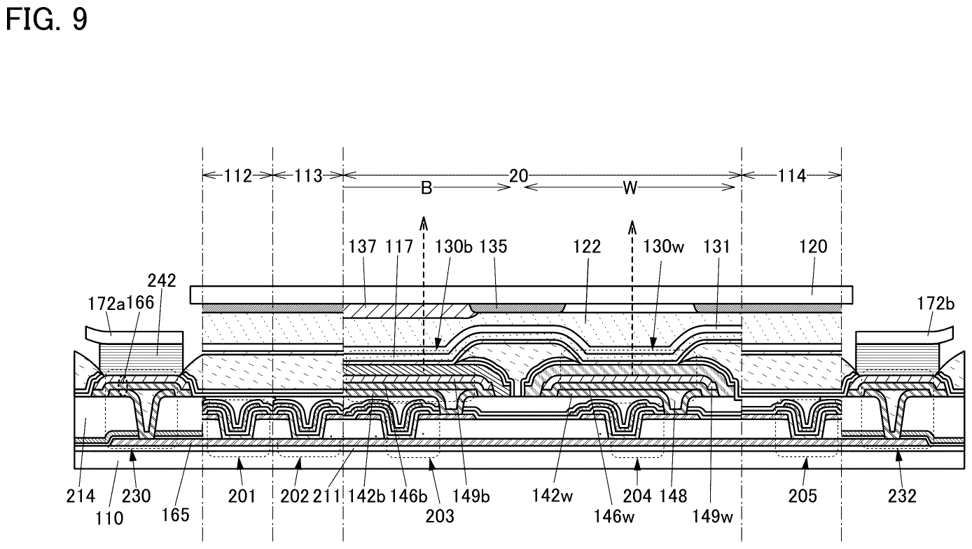

As illustrated in FIG. 9, a vertical transistor may also be used as each of the transistor 203 and the transistor 204 included in the display portion 20. With the use of the vertical transistor, the area occupied by the transistor is reduced, so that a correction circuit or the like can be easily incorporated into the pixel circuit.

An insulating layer 211, an insulating layer 213, an insulating layer 215, and the insulating layer 214 are provided in this order over the substrate 110. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited; each insulating layer can include two or more layers, not just one.

A material in which impurities such as water and hydrogen do not easily diffuse is preferably used for at least one of the insulating layers covering the transistors. In that case, the insulating layer can function as a barrier layer. Such a structure can effectively inhibit diffusion of impurities into the transistors from the outside and increase the reliability of the display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may also have a stacked-layer structure of an organic insulating layer and an inorganic insulating layer. The outermost layer of the insulating layer 214 preferably has a function of an etching protective layer. In that case, a depressed portion can be inhibited from being formed in the insulating layer 214 at the time of processing the conductive layer 142a, the conductive layer 146a, the conductive layer 149a, or the like. Alternatively, a depressed portion may also be formed in the insulating layer 214 at the time of processing the conductive layer 142a, the conductive layer 146a, the conductive layer 149a, or the like.

Each of the transistor 202 and the transistor 203 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a vertical transistor, a planar transistor, a fin-type transistor, a staggered transistor, an inverted staggered transistor, or the like can be used. Not only a top-gate transistor structure, but also a bottom-gate transistor structure can be employed. The gate can be provided on only one of the upper and lower sides of the semiconductor layer where the channel is formed, not necessarily on both sides.

The structure where the semiconductor layer where a channel is formed is held between two gates is used for each of the transistor 202 and the transistor 203. It is possible to drive the transistor by connecting the two gates and supplying the same signal to these gates. It is also possible to drive the transistor by applying a potential for controlling the threshold voltage to one of the two gates and a potential for driving to the other.

The semiconductor layer of the transistor preferably includes a metal oxide (also referred to as an oxide semiconductor). That is, an OS transistor including a metal oxide in its channel formation region is preferably used for the display apparatus of this embodiment. For the metal oxide that can be used for the OS transistor, the description in Embodiment 3 can be referred to.

All the transistors included in the display apparatus can be OS transistors. Alternatively, all the transistors included in the display apparatus can be Si transistors. Alternatively, some of the transistors included in the display apparatus may be OS transistors and the rest may be Si transistors.

Alternatively, an OS transistor may also be provided over a Si transistor. Alternatively, OS transistors may be stacked.

As examples of silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of Si transistors such as LTPS transistors, a circuit required to be driven at a high frequency (e.g., a source driver) can be formed on the same substrate as a display portion. Thus, external circuits mounted on the display apparatus can be simplified, and parts costs and mounting costs can be reduced.

When both an LTPS transistor and an OS transistor are used in the display portion 20, for example, a display apparatus with low power consumption and high driving capability can be obtained. A structure where an LTPS transistor and an OS transistor are used in combination is referred to as LTPO in some cases. In a more favorable example, it is preferable that an OS transistor be used as a transistor functioning as a switch for controlling electrical continuity and discontinuity between wirings and an LTPS transistor be used as a transistor for controlling current.

For example, one transistor included in the display portion 20 can function as a transistor for controlling current flowing through the light-emitting device and be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased in the pixel circuit.

By contrast, another transistor included in the display portion 20 functions as a switch for controlling selection and non-selection of a pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure that includes the OS transistor and the light-emitting device having an MML (metal maskless) structure. With this structure, the leakage current that might flow through the transistor and the leakage current that might flow between adjacent light-emitting devices (also referred to as lateral leakage current, side leakage current, or the like) can be extremely low. With the structure, a viewer can notice any one or more of the image crispness, the image sharpness, a high chroma, and a high contrast ratio in an image displayed on the display apparatus. When the leakage current that would flow through the transistor and the lateral leakage current between the light-emitting devices are extremely low, light leakage that might occur in black display (what is called black-level degradation) or the like can be minimized.

FIG. 8B and FIG. 8C illustrate other structure examples of the transistor that can be used as the transistor 203 and the transistor 204.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistors may also be provided.

FIG. 8B illustrates an example of the transistor 209 in which the insulating layer 225 covers the top surface and the side surface of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 8C, the insulating layer 225 overlaps with the channel formation region 231i of the semiconductor layer 231 and does not overlap with the low-resistance regions 231n. The structure illustrated in FIG. 8C can be formed by processing the insulating layer 225 using the conductive layer 223 as a mask, for example. In FIG. 8C, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 230 is provided in a region of the substrate 110 where the substrate 120 does not overlap. In the connection portion 230, the wiring 165 is electrically connected to the FPC 118 through a conductive layer 166 and a connection layer 242. An example is described in which the conductive layer 166 has a stacked-layer structure of a conductive film obtained by processing the same conductive film as the conductive layers 142b and 142w, a conductive film obtained by processing the same conductive film as the conductive layers 146b and 146w, and a conductive film obtained by processing the same conductive film as the conductive layers 149b and 149w. The conductive layer 166 is exposed on the top surface of the connection portion 230. Thus, the connection portion 230 and the FPC 118 can be electrically connected to each other through the connection layer 242.

As the connection layer 242, an anisotropic conductive film (ACF), an anisotropic conductive paste (ACP), or the like can be used.

Note that a connection portion 232 to which an FPC 119 is electrically connected can have a structure similar to the above.

The light-blocking layer 135 and the coloring layer 137 can be provided between the adhesive layer 122 and the substrate 120. The light-blocking layer 135 can be provided to include a region overlapping with a region between the adjacent light-emitting devices, and a region overlapping with the driver circuits 301, 302, and 303. The coloring layer 137 can be provided in a position overlapping with the light-emitting device 130b.

Both the light-emitting device 130b and the light-emitting device 130w emit white light. Since the light-emitting device 130b is a light-emitting device of a subpixel emitting blue light, the coloring layer 137 transmitting blue light is provided to overlap with the light-emitting device 130b. Since the light-emitting device 130w is a light-emitting device of a subpixel emitting white light, the coloring layer 137 is not provided over the light-emitting device 130w.

As each of the substrate 110 and the substrate 120, a substrate made of the materials that can be used for the substrate 402 described in Embodiment 2 can be used. Alternatively, a silicon substrate where an arithmetic circuit, a memory circuit, and the like are formed can be used as the substrate 110. A variety of optical members such as a circular polarizing plate can be provided on the outer surface of the substrate 120.

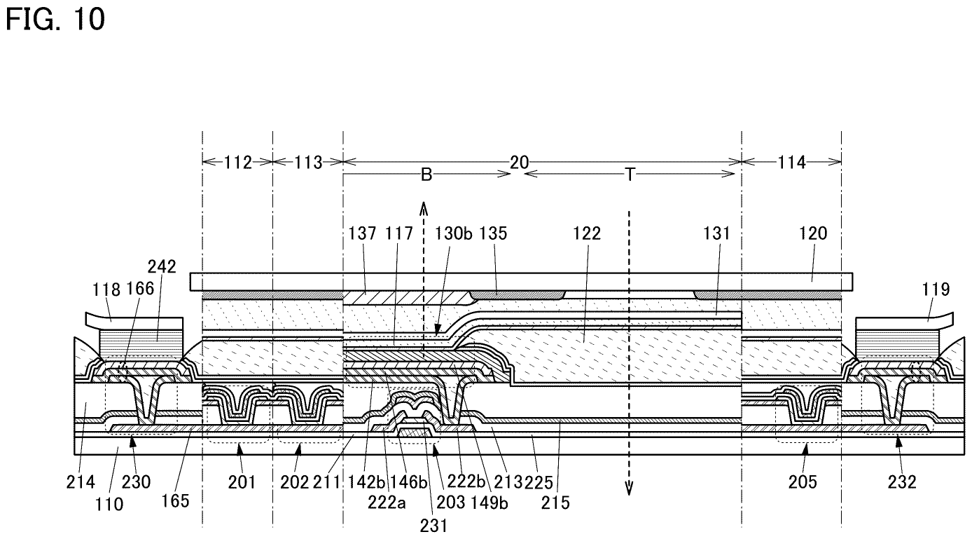

In FIG. 10, the pixel 11 including the subpixel B emitting blue light and the light-transmitting region T is illustrated in the display portion 20 as an example. In the light-transmitting region T included in the pixel 11, components of the transistor and the light-emitting device are provided as few as possible so that light is easily transmitted from the substrate 120 to the substrate 110. Note that components that are of a transistor and a light-emitting device included in an adjacent subpixel and formed using a material with a high visible light transmittance or a high light transmittance in the wavelength range from blue to red can be extended to the light-transmitting region T.

At least part of this embodiment can be implemented in combination with any of the other embodiments described in this specification as appropriate.

### Embodiment 5

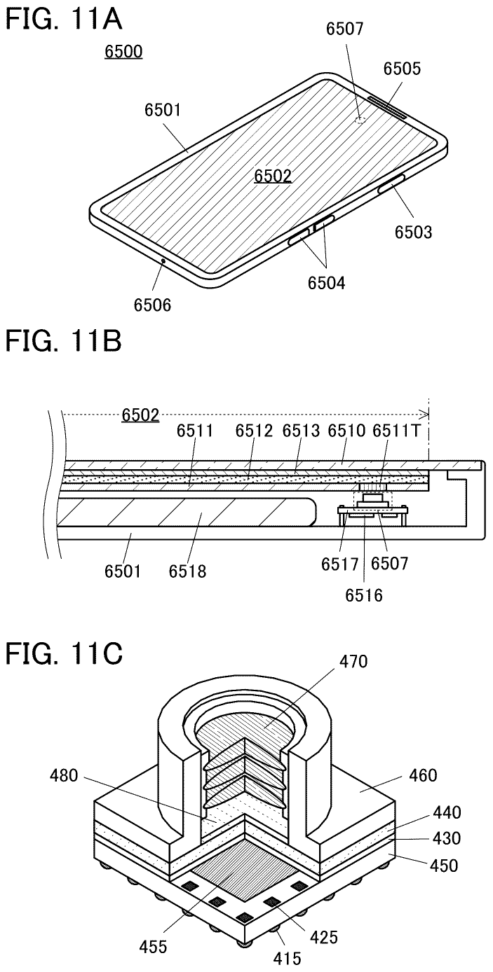

In this embodiment, an electronic device of one embodiment of the present invention will be described with reference to FIG. 11A to FIG. 11C. The electronic device of one embodiment of the present invention are used as portable information terminals such as a smartphone, a tablet computer, or the like.

The electronic device of one embodiment of the present invention includes the display apparatus of one embodiment of the present invention and a camera in a housing. The camera can be used as a front camera and is an under-display camera that is provided to overlap with a display portion of the display apparatus.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic appliance in this embodiment may also include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays).

The electronic appliance in this embodiment can have a variety of functions. For example, the electronic appliance in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device 6500 illustrated in FIG. 11A is a portable information terminal that can be used as a smartphone.

The electronic device 6500 includes a housing 6501, a display portion 6502, a power button 6503, buttons 6504, a speaker 6505, a microphone 6506, a camera 6507, and the like. The display portion 6502 has a touch panel function.

The camera 6507 can be used as a front camera and is provided at a position overlapping with the display portion 6502. The display apparatus of one embodiment of the present invention can be used in the display portion 6502. In the display apparatus of one embodiment of the present invention, the entire display portion can have uniform resolution, and an initial image can be obtained with the camera 6507 using a light-transmitting region provided in the display portion 6502.

Since the aperture ratio of the pixel can be increased, the display apparatus of one embodiment of the present invention has high light extraction efficiency and can display an extremely bright image. Furthermore, since the entire display portion 6502 has uniform resolution and the position of the camera 6507 is not easily visually recognized, natural display can be performed.

FIG. 11B is a schematic cross-sectional view including an end portion of the housing 6501 on the camera 6507 side.

A protection member 6510 having a light-transmitting property is provided on the display surface side of the housing 6501. A display panel 6511, an optical member 6512, a touch panel 6513, a battery 6518, the camera 6507, and the like are provided in a space surrounded by the housing 6501 and the protection member 6510.

The display panel 6511, the optical member 6512, and the touch panel 6513 are fixed to the protection member 6510 with an adhesive layer (not illustrated).

A lens of the camera 6507 is placed to overlap with a region 6511T having a high transmittance of the display panel 6511. The camera 6507 can be mounted on a printed circuit board 6517 fixed to the housing 6501. For example, an IC 6516 including an arithmetic apparatus and the like can be mounted on the printed circuit board 6517. The region 6511T corresponds to the display portion b illustrated in FIG. 1A.

The initial image obtained by image capturing by the camera 6507 is a low-quality image whose information is deficient due to shielding caused by pixels. The arithmetic apparatus included in the IC 6516 can perform image processing such as restoration of a defected portion of an image by inference, noise removal, and the like, so that a high-quality image can be generated. The display apparatus of one embodiment of the present invention is capable of capturing an image by using a light-transmitting region provided in a pixel and obtaining a high-quality image by image processing for improving the quality of the initial image. Note that artificial intelligence trained by deep learning or the like can also be used for the image processing.

FIG. 11C is an external perspective view of an example of a camera module made of a combination of an image sensor chip and a lens. The camera module can be used for the camera 6507.

A package including the image sensor chip is a CSP (Chip Size Package) and includes a bare chip 450 of the image sensor, a cover glass 440, an adhesive 430 that bonds them, and the like.

Electrode pads 425 provided on the outside of a pixel array 455 are electrically connected to back electrodes 415 via through electrodes. The electrode pads 425 are electrically connected to a circuit constituting the image sensor, with wirings or wires. Note that the bare chip 450 can be a stacked chip in which circuits having a variety of functions are stacked.

A BGA (Ball Grid Array) with a structure in which bumps are formed with solder balls as the back electrodes 415 is illustrated as an example. Note that, without being limited to the BGA, an LGA (Land Grid Array), a PGA (Pin Grid Array), or the like can be used. Alternatively, a package in which the bare chip 450 is mounted on a QFN (Quad Flat No-lead package) or a QFP (Quad Flat Package) may also be used.

A lens cover 460, a plurality of lenses 470, and the like are provided over the package. Furthermore, an optical filter 480 that absorbs light with a certain wavelength is provided as needed between the lens 470 and the cover glass 440. For example, in the case where the image sensor mainly performs visible light imaging, an infrared cut filter or the like can be used as the optical filter 480.

At least part of this embodiment can be implemented in combination with any of the other embodiments described in this specification as appropriate.

### REFERENCE NUMERALS

10: pixel, 11: pixel, 12: pixel, 13: pixel, 20: display portion, 30: camera, 31: lens, 41: substrate, 42: substrate, 100T: transistor, 101: layer, 110: substrate, 111b: pixel electrode, 111w: pixel electrode, 113_1: light-emitting unit, 113_2: light-emitting unit, 113_3: charge-generation layer, 113b: layer, 113w: layer, 114: common layer, 117: common electrode, 118b: mask layer, 118w: mask layer, 118: FPC, 119: FPC, 120: substrate, 122: adhesive layer, 125: insulating layer, 127: insulating layer, 130b: light-emitting device, 130w: light-emitting device, 131: protective layer, 135: light-blocking layer, 137: coloring layer, 142a: conductive layer, 142b: conductive layer, 142w: conductive layer, 146a: conductive layer, 146b: conductive layer, 146w: conductive layer, 148: layer, 149a: conductive layer, 149b: conductive layer, 149w: conductive layer, 165: wiring, 166: conductive layer, 201: transistor, 202: transistor, 203: transistor, 204: transistor, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 230: connection portion, 231i: channel formation region, 231n: low-resistance region, 231: semiconductor layer, 232: connection portion, 242: connection layer, 255a: insulating layer, 255b: insulating layer, 255c: insulating layer, 301: driver circuit, 302: driver circuit, 303: driver circuit, 402: substrate, 404e: conductive layer, 404: conductive layer, 406: insulating layer, 407a: insulating layer, 407b: insulating layer, 407c: insulating layer, 407: insulating layer, 408: semiconductor layer, 412a: conductive layer, 412b: conductive layer, 415: back electrode, 425: electrode pad, 430: adhesive, 440: cover glass, 441: opening, 450: bare chip, 455: pixel array, 460: lens cover, 470: lens, 480: optical filter, 6500: electronic device, 6501: housing, 6502: display portion, 6503: power button, 6504: button, 6505: speaker, 6506: microphone, 6507: camera, 6510: protection member, 6511T: region, 6511: display panel, 6512: optical member, 6513: touch panel, 6516: IC, 6517: printed circuit board, 6518: battery

1. A display apparatus comprising:
a first display portion; and
a second display portion,
wherein the second display portion is surrounded by the first display portion,
wherein the first display portion comprises a first pixel,
wherein the second display portion comprises a second pixel,
wherein the first pixel comprises a first subpixel, a second subpixel, a third subpixel, and a fourth subpixel emitting light of different colors, and
wherein the second pixel comprises a fifth to subpixel, a sixth subpixel, and a seventh subpixel emitting light of different colors and a light-transmitting region.

2. The display apparatus according to claim 1,
wherein an area occupied by a pixel and a pixel density are the same between the first display portion and the second display portion.

3. The display apparatus according to claim 1,
wherein each of the first subpixel and the fifth subpixel is configured to emit red light,
wherein each of the second subpixel and the sixth subpixel is configured to emit green light,
wherein each of the third subpixel and the seventh subpixel is configured to emit blue light, and
wherein the fourth subpixel is configured to emit white light.

4. The display apparatus according to claim 1,
wherein each of the first subpixel, the second subpixel, the third subpixel, the fourth subpixel, the fifth subpixel, the sixth subpixel, and the seventh subpixel comprises a light-emitting device emitting white light, and
wherein each of the first subpixel, the second subpixel, and the third subpixel and the fifth subpixel, the sixth subpixel, and the seventh subpixel emits light to the outside through a coloring layer.

5. The display apparatus according to claim 1,
wherein the first subpixel, the second subpixel, the third subpixel, and the fourth subpixel are arranged in a matrix, and
wherein the fifth subpixel, the sixth subpixel, and the seventh subpixel are arranged in a manner similar to that of the first subpixel, the second subpixel, and the third subpixel.

6. A display apparatus comprising:
a first display portion; and
a second display portion,
wherein the second display portion is surrounded by the first display portion,
wherein the first display portion comprises a first pixel,
wherein the second display portion comprises a second pixel,
wherein the first pixel comprises a first subpixel, a second subpixel, a third subpixel, and a fourth subpixel,
wherein the second pixel comprises a fifth subpixel, a sixth subpixel, a seventh subpixel, and an eighth subpixel and a light-transmitting region,
wherein each of the first subpixel and the fifth subpixel configured to emit red light,
wherein each of the second subpixel and the sixth subpixel is configured to emit green light,
wherein each of the third and subpixel and the seventh subpixel is configured to emit blue light,
wherein each of the fourth subpixel and the eighth subpixel has is configured to emit white light,
wherein an area of the eighth subpixel is smaller than an area of the fourth subpixel, and
wherein an area occupied by a pixel and a pixel density are the same between the first display portion and the second display portion.

7. The display apparatus according to claim 6,
wherein each of the first subpixel, the second subpixel, the third subpixel, the fourth subpixel, the fifth subpixel, the sixth subpixel, the seventh subpixel, and the eighth subpixel comprises a light-emitting device emitting white light, and
wherein each of the first subpixel, the second subpixel, and the third subpixel and the fifth subpixel, the sixth subpixel, and the seventh subpixel emits light to the outside through a coloring layer.

8. The display apparatus according to claim 1,
wherein each of the first pixel and the second pixel comprises a transistor comprising a metal oxide in a semiconductor layer.

9. The display apparatus according to claim 8,
wherein a channel formation region of the transistor is provided along a side surface of an insulating layer.

10. An electronic device comprising the display device according to claim 8, and a camera,
wherein the second display portion comprises a region overlapping with a lens of the camera.

11. The display apparatus according to claim 6,
wherein each of the first pixel and the second pixel comprises a transistor comprising a metal oxide in a semiconductor layer.

12. The display apparatus according to claim 11,
wherein a channel formation region of the transistor is provided along a side surface of an insulating layer.

13. An electronic device comprising the display device according to claim 11, and a camera,
wherein the second display portion comprises a region overlapping with a lens of the camera.
